(19) United States
(12) Patent Application Publication
(10) Pub. No.: US 2024/0420787 A1
(43) Pub. Date: Dec. 19, 2024

(54) CHARGE DOMAIN DIGITAL, GENERATIVE PRE-TRAINED TRANSFORMER (GPT) AND DIGITAL STORAGE

(71) Applicant: AIStorm Inc., Houston, TX (US)

(72) Inventor: David SCHIE, Houston, TX (US)

(73) Assignee: AIStorm Inc., Houston, TX (US)

(21) Appl. No.: 18/742,223

(22) Filed: Jun. 13, 2024

Related U.S. Application Data
(60) Provisional application No. 63/472,798, filed on Jun. 13, 2023.

(51) Int. Cl. G11C 27/04; G11C 19/28; G11C 27/00

(52) U.S. Cl. CPC G11C 27/04; G11C 19/282; G11C 27/005

(57) ABSTRACT

Digital circuits, and other types of circuits, may be implemented using improved charge domain techniques based on modern silicon processing compatible with standard digital flows. An example of technology that can be used for charge domain digital flows are FINs (as used in FinFET) which can be modified to produce charge domain shift registers and charge domain digital logic. Also, novel notch based implementations which overcome limited potential range, speed, complex clocking and density issues of older generations of charge domain technology may be disclsoed. Such implementations can significantly improve performance, density and reduce power consumption of charge domain digital circuits, with the proper implants and process modifications.

### RELATED APPLICATIONS

This patent application is related to U.S. Provisional Application No. 63/472,798 filed Jun. 13, 2023, entitled “Charge Domain Digital, GPT & Digital Storage”, in the names of the present inventors and which is incorporated herein by reference in its entirety. The present patent application claims the benefit under 35 U.S.C § 119 (e) of the aforementioned provisional application.

### TECHNICAL FIELD

The present application in general relates to digital circuits, and more specifically, to how digital circuits, and other types of circuits, may be implemented using improved charge domain techniques based on modern silicon processing compatible with standard digital flows.

### BACKGROUND

Digital circuits are used extensively in personal computers (PCs), cell phones, servers, and numerous other devices. Some examples of digital circuits may include, but are not limited to digital processors, artificial intelligence graphical processing units (AI GPUs), microcontrollers and state machines. Digital is the concept of binary representation of numbers to ease electronic processing. Today's digital circuits, however, are almost universally implemented by using transistors, usually metal oxide silicon field effect transistors (MOSFETs). Fabricators, electronic design automation (EDA) tool set vendors, and device makers have created “digital flows” which take software written in a high-level programming language such as Verilog or Hardware Description Language (HDL) and convert these to register level implementations and finally synthesize the result into transistor-based features on silicon or other substrate.

An alternative to transistor based digital logic is to use charge domain structures to actuate charge movement in conformance with a logic function. Many years ago such structures (i.e., 1970's and 1980's) were proposed using charge coupled device (CCD) methods based on metal oxide semiconductor (MOS) capacitor structures operated between deep depletion and weak inversion. However, these structures were limited by the long time constants associated with charge movement between charge storage elements, limited potential range to spill charge from one bucket to the other, and the limitations of silicon processing at the time. These structures also had unique multi-cycle clocking which would not be compatible with today's standard digital flows.

Modern technologies with smaller lithographies and sophisticated implant control show the promise of producing digital circuits that were not possible in the 1970's and 1980's, but these processing capabilities have so far only been applied to improve transistor based digital implementations. Transistors have followed Moore's law improving dramatically since that time, but charge domain digital devices have not benefitted from similar evolution.

Therefore, it would be desirable to provide a device and method that overcomes the above.

### SUMMARY

In accordance with one embodiment, a digital circuit is disclosed. The digital circuit has at least one source of a charge. At least one output charge storage element is provided. At least one transfer gate or sink is provided wherein movement of the at least one transfer gate or sink allows logic gate functionality. Control inputs are coupled to the transfer gates or charge sinks controlling transfer or removal of the charge. The control inputs performing one of producing or removing the charge on the at least one output storage element responsive to the control inputs so the digital circuit performs a digital logic function.

In accordance with one embodiment, a NAND ID and Transfer Logic Gate (ITGL) is disclosed. The NAND ID and Transfer Logic Gate (ITGL) has an input diode coupled to a first control input. A transfer gate is coupled to a second control input. An output memory node is provided, wherein an input diode potential is below a minimum potential of the output memory node when the first control input is high, wherein the transfer gate blocks conduction when the second control input is low, such that only when the input diode potential minimum is raised and a barrier is lowered can charge move to the output memory node.

In accordance with one embodiment, an inverter ID and Transfer Logic Gate (ITGL) is disclosed. The inverter ID and Transfer Logic Gate (ITGL) has an input diode coupled to a control input. An output charge storage element adjacent to the control input is provided. The input diode when the control input is low will bring charge above the potential of an output node causing charge to transfer to the output charge storage element and when high will sink charge previously in the output node emptying it.

In accordance with one embodiment, a charge domain shift register is disclosed. The charge domain shift register has a plurality of charge storage elements. These elements may be adjacent elements comprising a charge coupled shift register or a plurality of transfer gates may separate the plurality of charge storage elements. The memory nodes and transfer gates are fabricated on a fin similar to the fin of a FinFet.

In accordance with one embodiment, a charge domain shift register is disclosed. The charge domain shift register has a source of charge. A plurality of charge storage elements is provided. An output charge storage element is coupled to the plurality of charge storage elements. A plurality of notch type transfer gates separates the plurality of charge storage elements. Control inputs are coupled to the notch type transfer gates. The charge is moved through the charge domain shift register by clocking the control inputs.

In accordance with one embodiment, a logic circuit is disclosed. The logic circuit has two sources of charge. A summing memory node is provided. Notch gates couple the two sources of charge to the summing node. A carry memory node is coupled through a fixed barrier to the summing node, where a fixed barrier potential height is set relative to a summing node potential such that if all AND inputs to the summing node transfers charge to the summing node then charge transfers to the carry memory node over the fixed barrier, but if less than all AND inputs to the summing node transfers charge to the summing node then charge does not transfer to the carry memory node. A sense gate is coupled to the carry memory node, wherein the sense gate further actuates a sink when charge is detected on the carry memory node, and where the sink is coupled to the summing memory node to remove the charge from the summing memory node in conformance with a signal from the sense gate. Thus XOR functionality is disclosed. If the sense gate is considered a carry output then half adder functionality is disclosed.

In accordance with one embodiment, a full adder is disclosed. An additional input is provided to that of the XOR function above and a second carry is added as a barrier to the first with its own sense gate. If only one unit of charge (only one input contains charge) is input, it will be captured by the summing node. If two units are present then one unit will charge the summing node and the second will flow over a barrier to a first sense gate. In this case the sense gate will actuate a sink to remove the charge from the summing node. If a third unit is present then the second sense gate will accept charge and may actuate a barrier to a source of charge to refill the summing node. If the first sense gate is considered the carry then full adder functionality is obtained.

In accordance with one embodiment, a 4×4 multiplier is disclosed. Said multiplier includes multiple two input AND gates further coupled to combinations of full adders, half adders, gate logic such as inverters and output memory nodes;

In accordance with one embodiment, a series to parallel converter is disclosed. The series to parallel converter has an input source of charge. A plurality of charge based shift registers is provided, wherein a first charge based shift register is coupled to the input source of charge, a remaining plurality of charge based shift registers orientated at an angle to each element of the first charge based shift register. An output charge storage element is coupled to each of the remaining plurality of shift registers, wherein the first shift register accepts series information from the input source of charge and provide the series information as parallel.

In accordance with one embodiment, a serdes is disclosed. The serdes has a transmitter and receiver, where said transmitter is a parallel to series converter, comprising: multiple parallel input sources of charge; a charge based shift register, wherein a first charge based shift register is coupled to the input sources of charge, and then clocked by the size of the input bus; an output charge storage element coupled to the output of said charge based shift register; and an output sense gate which places serial data onto a bus. And a receiver wherein said receiver accepts serial information from a first shift register and a shift register at an angle to said first shift register accepts serial information as parallel according to the width of the bus and a sense gate then provides the series information as parallel. As part of the VCO, a pair of notch transfer gates separates sources of charge from a memory node, wherein the notch transfer gates can one of move or remove charge from the memory node, and wherein the memory node is coupled to a sense gate which is coupled to a control node of a VCO used in the serdes. A part of a fractional n capability a charge domain sigma delta loop may be included to allow fractional frequency generation.

In accordance with one embodiment, a general purpose transformer is disclosed. The transformer has one or more charge based shift registers, wherein encoder and decoder layers of the transformer are built from the charge based shift registers.

In accordance with one embodiment, a machine training device is disclosed. The machine learning training device has one or more charge based shift registers responsive to an error function, wherein input information, tokens, values, keys, weights and other variables are stored in charge based shift registers, wherein a training algorithm follows a contour in conformance with the error function by perturbing weights of the error function.

In accordance with one embodiment, a field programmable gate array is disclosed. The field programmable gate array has charge domain logic (CDL) function coupled to a plurality of charge based shift registers where sense gates may be selected to choose the output of each gate desired. An input map corresponding to desired logic functions is provided. A multiplexer is coupled to the input map to sense gates to the shift registers and the shift registers to logic components so as to produce a succession of logic functions.

In accordance with one embodiment, a dynamic digital memory structure is disclosed. The dynamic digital memory structure has a plurality of charge based shift registers, wherein the plurality of charge based shift registers are one of one dimensional or two dimensional charge based shift registers.

In accordance with one embodiment, a circuit to set a depth of a notch gate is disclosed. The circuit to set a depth of a notch gate has a charge storage memory node. A charge domain notch gate is coupled to the charge storage memory node. Two capacitors connected in series is provided. A first current source is coupled between a supply and a non-shared terminal of a first capacitor of the two capacitors. A second current source is coupled to a shared terminal of the two capacitors and ground or supply. A third current source is coupled from a supply to the non-shared terminal of the second capacitor. A first switch is connected between the non-shared terminal of the first capacitor and ground. A second switch is connected between the shared terminal of the two capacitors and ground. A comparator is connected to the shared terminal of the two capacitors and ground, the comparator coupled to actuate the third and second current sources, when the shared terminal potential of the two capacitors is below ground. A split gate over the first (no implant) and second (n+ implant) portion of the notch gate, connected across the second capacitor allows control of the notch depth. With this method it may not be nessary to include the n+ implant. Connecting on or other of the terminals of the second capacitor to a control gate will allow the leftmost element (with no implant) and the notch to move together based upon the control gate voltage. Usually the middle nose is used to connect the control gate with all switches and current sources off after the initial calibration.

In accordance with one embodiment, a VCO control register is disclosed. The VCO control registered has a source of input charge. A first charge based memory node is coupled to the source of input charge by a notch gate. A second charge based memory node whose charge level is set below a set charge based memory node is coupled to the first charge based memory node by a notch gate. A sense gate is coupled to the first charge based memory node and an oscillator voltage based frequency control register, wherein the oscillator frequency is regulated by control inputs which actuate the transferring of charge into and out of the first memory node to increase and decrease the voltage of the voltage based frequency control register.

### BRIEF DESCRIPTION OF THE DRAWINGS

The present application is further detailed with respect to the following drawings. These figures are not intended to limit the scope of the present invention but rather illustrate certain attributes thereof.

FIG. 1A-1B show an exemplary charge domain shift register and operation in accordance with one aspect of the present application;

FIG. 2A-2D are exemplary block diagrams of an OR gate (‘+’ operator), an AND gate (‘&’ operator), an XOR gate (‘+’ contained within a circle) and a half adder in accordance with one aspect of the present application. If the SG used to discharge the summing node for XOR operation is also considered as a carry indicator then a half adder is produced;

FIG. 3A is an exemplary ID and transfer gate logic (ITGL) NAND gate in accordance with one aspect of the present invention.

FIG. 3B is an exemplary ID and transfer gate logic (ITGL) inverter in accordance with one aspect of the present invention;

FIG. 4 is an exemplary transfer gate logic (TGL) AND gate in accordance with one aspect of the present application;

FIG. 5A-5B are block diagrams of exemplary parallel-in-parallel out (PIPO) and serial-in-serial-out (SISO) shift registers built from flip flops in accordance with one aspect of the present application;

FIG. 6 is a schematic of an exemplary diagram of a pulse triggered flip flop implemented using transistors flops in accordance with one aspect of the present application;

FIG. 7A shows exemplary technology computer aided design (TCAD) simulation results from a Fin based shift register whose parameters have been extrapolated into a surface simulation in accordance with one aspect of the present application;

FIG. 7B shows a pinned memory node (MN) coupled by a transfer gate (TG) to a floating diffusion in accordance with one aspect of the present application;

FIG. 8A shows an exemplary notch gate in accordance with one aspect of the present application as well as a circuit to set the the notch depth;

FIG. 8B shows potential diagrams during operation of the notch gate of FIG. 8A in accordance with one aspect of the present application;

FIG. 9A shows an exemplary notch and barrier charge domain logic (NBCDL) OR gate in accordance with one aspect of the present application;

FIG. 9B shows potential diagrams for the NBCDL OR gate of FIG. 9A in accordance with one aspect of the present application;

FIG. 10 shows the block diagram of an exemplary AND/OR gate in accordance with one aspect of the present application;

FIG. 11 shows the block diagram of an exemplary inverter in accordance with one aspect of the present application;

FIG. 12 shows an exemplary NBCDL inverter in accordance with one aspect of the present application;

FIG. 13A shows an exemplary mixed logic in accordance with one aspect of the present application;

FIG. 13B shows potential operation diagrams for the mixed logic of FIG. 13A in accordance with one aspect of the present application;

FIG. 14 shows a block diagram of an exemplary NBCDL half adder in accordance with one aspect of the present application;

FIG. 15 shows a layout of an exemplary NBCDL half adder including a thyristor sense gate in accordance with one aspect of the present application;

FIG. 16 shows a block diagram of full adder using two sense gate thyristors in accordance with one aspect of the present application;

FIG. 17 shows a portion of a 4×4 multiplier in accordance with one aspect of the present application, in this case three two input AND gates and a full adder, the combination further labelled as FA6N in FIG. 18;

FIG. 18 shows an exemplary embodiment of multiplication of two 4 bit numbers in accordance with one aspect of the present application;

FIG. 19 shows an exemplary embodiment of a FinFET to illustrate how compact a shift register implemented using FinFET technology in accordance with one aspect of the present application;

FIG. 20 shows a basic block diagram of an exemplary embodiment of a phase lock loop (PLL) in accordance with one aspect of the present application;

FIG. 21 shows a block diagram of an exemplary embodiment of a Serdes concept in accordance with one aspect of the present application;

FIG. 22A-22B shows an exemplary embodiment of notch gates to create a PLL charge pump with the center MN as the control register for a VCO in accordance with one aspect of the present application;

FIG. 23 shows an exemplary embodiment of a charge sigma delta created using gates and shift register delays in accordance with one aspect of the present application;

FIG. 24A illustrates an exemplary concept of a horizontal series shift register which after loading moves its charge information vertically into a succession of parallel shift registers in accordance with one aspect of the present application. The shift register also may be two dimenisons shift registers;

FIG. 24B illustrates an exemplary concept of a wired device which may be used to replicate a charge level in accordance with one aspect of the present application;

FIG. 25 shows an exemplary embodiment of the encoder, decoder and attention model for a generative pre-trained transformer in accordance with one aspect of the present application;

FIG. 26 illustrates an exemplary embodiment of the encoder, decoder, attention and positional encoding concepts in a simple translation application in accordance with one aspect of the present application;

FIG. 27 shows an exemplary embodiment of the procedure behind bitcoin block hashing (block chain operation) in accordance with one aspect of the present application;

FIG. 28 shows an exemplary embodiment of how block hashes are formed in accordance with one aspect of the present application;

FIG. 29 shows an exemplary input to be hashed turned into equivalent binary inputs in accordance with one aspect of the present application;

FIG. 30 shows an exemplary logic truth table required for SHA-256 in accordance with one aspect of the present application;

FIG. 31 shows an exemplary charge coupled shift register on a fin in accordance with one aspect of the present application;

FIG. 32 shows a five transistor flip flop in accordance with one aspect of the present application;

FIG. 33 shows a replica charge circuit in accordance with one aspect of the present application; and

FIG. 34 shows a neuron or timing circuit utilizing two MNs, two notch gates and a thyristor actuated through a vertical capacitor.

### DESCRIPTION OF THE APPLCIATION

The description set forth below in connection with the appended drawings is intended as a description of presently preferred embodiments of the disclosure and is not intended to represent the only forms in which the present disclosure can be constructed and/or utilized. The description sets forth the functions and the sequence of steps for constructing and operating the disclosure in connection with the illustrated embodiments. It is to be understood, however, that the same or equivalent functions and sequences can be accomplished by different embodiments that are also intended to be encompassed within the spirit and scope of this disclosure.

Embodiments of the present invention may disclose digital circuits, and other types of circuits, that may be implemented using improved charge domain techniques based on modern silicon processing compatible with standard digital processing and EDA flows. An example of technology that can be used for charge domain digital flows may be FINs as used fin shaped field effect transistors (FinFET) which can be modified to produce charge domain shift registers and charge domain digital logic. Also taught may be notch-based implementations which overcome limited potential range, speed, complex clocking, and density issues of older generations of charge domain technology. Such implementations may significantly improve performance, density and reduce power consumption of charge domain digital circuits, with the proper implants and process modifications.

In recent years process lithography improvements and implant technology have made significant leaps forward. Today, it may be possible to create silicon devices capable of manipulating charge with noise levels of less than one electron and “dark currents” in the range of electrons to tens of electrons per second (e-/s). These devices are typically focused on analog manipulation of charge or more specifically for storing charge information for a period of time without noise contamination for devices such as image sensors with global shutter functionality. This has led to a variety of processes with sophisticated implant control and special processing features typically focused upon integrating a light collection element with devices capable of storing the analog charge information temporarily and then converting it to a voltage analog form and finally into digital representation. Until now, process improvement efforts have almost exclusively focused upon light collection structures, structures for correlated double sampling (CDS) and low noise memory node analog charge storage, so much so that an industry inventory of devices labelled as nT pixels (4T, 5T, 6T, 7T, 8T, etc.) which labor to implement efficient mechanisms for light collection, low noise integration, noise removal, analog storage and transfer to analog voltage or digital form have resulted. The use of modern process technologies capable of forming unique device features which were previously not possible, used to fabricate modern pixels, can instead be used to create features for complex digital processing and memory structures in a way that has not been done before. One of the devices used in pixels is a pinned photodiode (PPD) which is a sandwich (p+/n in psub structure) with p+ at the surface to pin the device and an n region for collecting charge. A PPD that is not exposed to light is often called a memory node or MN and has a similar structure other than those facets related to light exposure. A PPD can be thought of as a bipolar device with its emitter and collector shorted or as a JFET. It has a lot of advantages as a charge storage receptacle. A MN can also be a MOS capacitor operated from deep depletion to weak inversion.

Instead of using charge domain processes to create devices for the storage of analog charge information, in for example global shutter pixels, there is significant motivation to produce digital circuits, including logic and memory, utilizing modern charge-based process capability. More specifically, a digital charge-based circuit may be a circuit in which the charge-based storage elements containing charge may be designated as a digital ‘1’ and those which do not may be designated as a digital ‘0’. A threshold between the two states (where some latent charge may still be considered a ‘0’ and less than full charge may be considered a ‘1’ may retain the benefit that transistor based digital circuits have with respect to being process and temperature independent, but could take advantage of the extremely high signal to noise ratios (SNR's) being achieved to produce digital functionality using a fraction of the number of electrons being used in transistor based digital circuits. This may result in lower power and higher performance. Additionally, these circuits could take advantage of structures such as a FINs which promise to enhance the forces that move charge in charge domain structures to produce faster and more efficient circuits such as the fringing effect.

We start by defining charge domain logic (CDL) as logic devices, shift registers or memory implemented using charge domain processes enabled elements such as: i) charge storage elements including floating diffusions (FDs) and pinned memory nodes (MNs or PPDs); ii) where the charge storage elements may be either separated by transfer gates (TGs) which lower the barrier between such elements; or iii) where the charge storage elements may represent a charge coupled structure where charge may transfer between depletion regions of MOS capacitor-elements (charge coupled device (CCD) or bulk-channel charge-coupled device (BCCD) based on the potential on the gates of the MOS capacitor elements; iv) notch and barrier elements created by gates, split gates, sinks or fixed barriers to control the collection and movement of charge; v) shift registers built from elements of the above to move charge or store information (memory); vi) wired devices (diodes with metal connection) to read potential (for example an FD) or to replicate a known charge elsewhere on the silicon; vii) input diodes (IDs) allowing a source of charge or to create sinks; viii) a novel charge injector circuit to control charge ratios input to notch gates or barriers (to program their potential height or depth); viii) the use of FIN structures to allow partial wrap around of gates and fabrication of charge domain devices on low parasitic FINs; ix) sense gates implemented by floating diffusions and/or thyristors, resets, followers, MOSFETs or bipolar transistors capable of being actuated by small changes in charge or potential; x) the use of sense gates to actuate other devices (barriers, sinks, followers, etc.) based on the movement of charge. Digital processing may be done based just on input state, positive or negative edges, or clock potential depending upon the desired methodology. Logic inputs and outputs may be accepted or provided as charge or potential on gates or wires, or combinations thereof.

Although gains may be attained by utilizing unique logic structures such as shift register based logic, it is desirable to be compatible with existing electronic design automation (EDA) structures such as those offered by companies like Synopsis or Cadence Design Systems such that high level logic languages such as Verilog or HDL may be used to implement designs in a conventional way, while allowing the new logic taught herein to be implemented during optimization, register transfer level (rtl) and place & route. This may result in faster and lower cost adoption of charge domain digital technology.

The motivations to utilize CDL rather than transistor techniques include the following. First, charge based digital may be more power efficient than transistor-based logic. CDL may be more efficient than transistor based implementations because: i) the improved noise performance may allow for a smaller number of electrons to be moved than required by an equivalent transistor based functionality through a similar potential; ii) in many structures, for example shift registers, the charge may be maintained during shifts rather than flushed and replaced as with transistor based structures; iii) there may be no shoot through current as with transistor based structures, and reduced parasitic capacitance to fill, during the equivalent of the finite switching time of transistor based switch structures connected in series between power and ground; iv) gates of TGs or (B) CCD structures may be less capacitive in optimized structures due to less fringe capacitance than a MOSFET (e.g. only Cgate, no Cgd, Cgs, Cdb) and offer the opportunity to include STI and implants to reduce capacitance. CDL memory is more compact than transistor based memory and requires fewer electrons to store information, resulting in shorter and less wiring between logic elements and memory reducing the parasitic time constants on the routing and clock structures required to operate at a given performance (frequency) and the power required to drive their capacitance.

Second, charge based digital may be more compact than transistor based digital logic. CDL may be more compact than transistor based digital logic because: i) charge storage elements may be placed at the minimum allowed gate density between each other without the spacing required for the drain or source diffusions of MOSFETs; ii) devices may be smaller than MOSFETs due to the reduced peak currents (and therefore area) required by the MOSFETs to meet performance (frequency) goals (transition); iii) many structures, for example shift registers, may require fewer elements to produce the equivalent functionality and therefore may be smaller; iv) TGs and barriers, notches or sinks created by implants may provide functionality with smaller geometries than transistors; v) local decoupling capacitance may be reduced due to the smaller combined shoot through currents of CDL components, as may power and ground routing and metal trace widths.

Third, charge based memory may be more compact than transistor-based memory, saving area and also reducing latency. Transistor based memory elements may be inherently multiple transistor (bistable) devices. CDL memory is generally little more than a bucket with charge or without charge. The bucket itself is on the order in size of each of the multiple switches required for transistor-based memory or much smaller in the case of devices with large drain and sources. This means that the memory may be more compact, and therefore the metallization required to communicate information to the memory and within the memory can be shorter and less wide. As memory requirements add up, the wiring between logic elements and memory can become a large factor in die size, latency, and power. CDL memory also offers the ability to accept charge directly and shift it into two dimensional charge domain shift register pages without converting between wired based potential devices and semiconductor structures. This can also reduce clocking and logic complexity and die area.

One can now define three types of digital gate structures: i) structures where control (logic or clocking) potential inputs may be applied to gates (transfer gate logic or TGL) e.g. MOS capacitor gates (e.g. (B) CCD based charge domain logic), where TGs, or input diodes and outputs are provided as a potential on a wire; ii) structures where inputs may come from other charge storage structures or input diodes and outputs may be provided as a charge; or iii) hybrid structures where some inputs may come from potential (voltage) inputs on gates or from charge charge and where outputs may be provided as wired outputs or as charge outputs. In wired output implementations it may be sufficient to provide a limited potential against a threshold or it might be convenient to utilize sense gate devices such as thyristors or other sense elements to bring the output to the power rail or ground or fully charge or discharge a charge domain storage element so as not to fall below a threshold related to charger transfer efficiency (CTE) over multiple moves.

### (B)CCD Logic

On a transient basis, MOS capacitors can be operated in a range of deep depletion through weak inversion. If a voltage is placed upon the gate of the MOS capacitor and no source of free electrons is available, then the fixed negative ions in the crystal lattice may have to counter the positive potential on the gate and a depletion region may extend into the silicon. The depth of this depletion may be a minimum level that may be proportional to the gate voltage and as such it may be modulated deeper or shallower using the gate voltage as a control node. If a source of free electrons is made available, for example by putting a diode (n+ diffusion in a p substrate) next to the gate of the MOS capacitor and then the voltage on the diode is reduced until the potential level of electrons is higher than the depletion depth of the adjacent MOS capacitor, then they may migrate into the depletion region under the MOS gate. If we use a “bucket” analogy, then the bucket created by modulating the depth of the depletion region under the MOS capacitor may fill up to the potential level of electrons of the adjacent ID. If we add a second MOS capacitor to the right of the first, and bias this MOS capacitor such that the depletion minimum level is lower than that on the MOS capacitor to its left, then once the diode electron potential exceeds the depletion potential minimum of the left MOS capacitor it may flow over the barrier into the rightmost most capacitor and fill it up to the diode electron potential level as if the charge were water. Once the rightmost bucket under the rightmost MOS capacitor is full to the diode electron potential level, the voltage on the gate of the leftmost MOS capacitor may be lowered to raise it as a barrier, or the diode voltage may be raised pushing the electron potential level lower, and the barrier may in either case separate the rightmost MOS capacitor from the source of charge.

Additional MOS capacitors may be added to the right of the two already formed MOS capacitors. By lowering potential bottom of this bucket (raising the gate voltage), charge may move to the right as if the succession of MOS capacitors were a shift register. Rather than refer to buckets we will now refer to charge storage bins or nodes or MNs (memory nodes).

The above example of a surface CCD shift register (SCCD) may be improved by n-doping the region just below the oxide layer to form a depletion region. The ionized positive carriers in this depletion region may transform the voltage on the gate to an even higher channel potential than would have existed at the surface of the SCCD device. Now the maximum channel potential (bottom of the bucket) is pushed deeper into the silicon rather than being at the surface below the oxide layer and free electrons will avoid the surface state disadvantages of SCCDs, improving charge transfer efficiency and leakage.

There may be three major forces associated with the movement of charge between bins: i) thermal diffusion; ii) self-induced drift and; iii) fringing fields. Fringing fields may be related to the influence that the potential on the gates of the adjacent bins exert on the discharging bin and are one of the most important design parameters to create fast movement of charge.

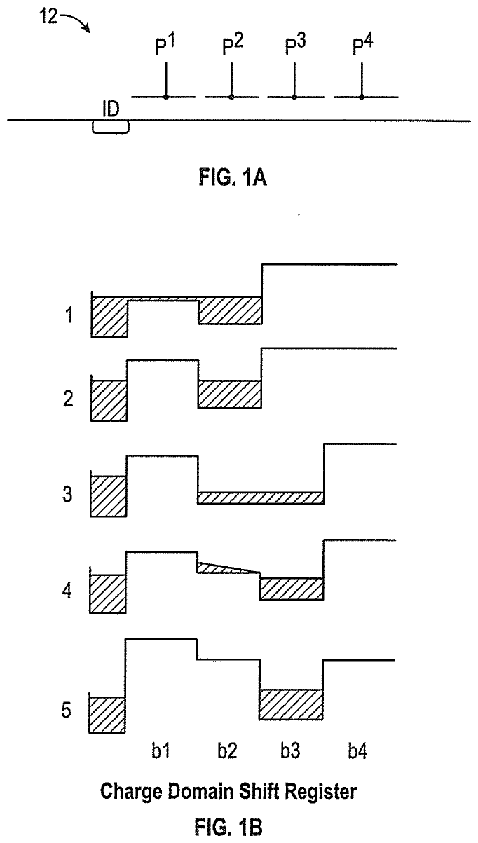

Referring to FIG. 1, a charge coupled device (CCD) 12 may be shown. In accordance with one embodiment, the CCD 12 may be a charge domain (CD) shift register. The CCD 12 may have four gates p1-p4 and four bins b1-b4, with a respective bin located under a corresponding gate. In this case an input diode (ID) provides the input charge.

In operation, one may refer to raising or lowering the gate of the MOS capacitor, where lowering the gate potential may mean making it negative, and where raising the potential on the gate may expand the depletion region or make the bin deeper and lowering it may reduce the size of the depletion region or make the bin smaller. Alternatively, one may refer to the bin, or to the bin as a barrier, in which case raising the barrier may mean making the depletion region smaller, or lowering the barrier may mean making the depletion region larger (i.e., raising the barrier means moving up the minimum potential or extent of the bin, and lowering the barrier means moving down the minimum potential or extent of the bin). These two descriptions are opposites so care should be taken to refer to the correct element, gate or bin/barrier. A fixed bin (created with an implant) which has a lower potential than an adjacent bin may be considered a sink. A fixed bin which has a higher potential than the minimum of an adjacent bin (created with an implant) which may be controlled may be called a barrier.

With respect to FIG. 1, initially at (1) the potential on the gate of p1 may be lower than that on the gate of p2, and the potentials on the gates of p3 and p4 may be low. The ID may fill the bin b2 under p2 with charge which moves like water over the p1 barrier. Then, at (2), the p1 barrier is raised to isolate the charge in bin b2 under p2 from the ID. At (3), the bin b3 under the gate p3 is lowered such that the charge flows from bin b2 to bin b3. At (4), as the bin b2 under the gate p2 is raised all of its charge is transferred into the bin b3 until at (5) an output charge sits in the bin b3 for further use.

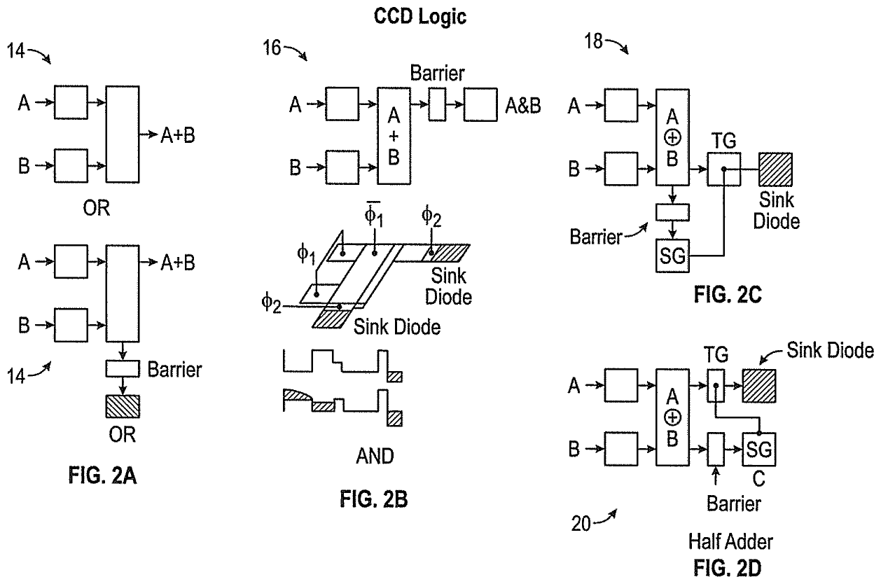

Referring to FIG. 2A, a simple OR gate 14 using CCD technology may be shown. In this case we assume that input bins A, B (hereinafter bins A, B) may be loaded with input states, ‘1’ or ‘0’. A bin A, B containing charge is a digital ‘1’ and an empty bin is a digital ‘0’. In the manner described above, one may move the charge from bins A and B into a shared charge storage bin during one cycle. If either or both of the bins A, B are high then charge will flow into the shared gate which represents the OR'ed output. As the charge on this larger charge storage bin A+B is twice that of the input bins A, B, it may contain twice the charge for two ‘1’ inputs. We can provide a barrier set to a single charge potential height which sinks to a diode to “scoop off” half of the charge so that one unit of charge remains in the output bin. This may be shown at the bottom of FIG. 2A. This could also have been accomplished with a sink sized to remove half the charge.

Alternatively, one can add a barrier equal to the height of charge represent by only A or B containing charge such that if both contain charge then charge will flow over the barrier into a second MN. This MN would represent AND functionality as illustrated in FIG. 2B. In both the AND 16 and the OR 14 cases, one can reset the gates for subsequent use by lowering a barrier to a diode set at the minimum charge storage bin potential. One can also create a charge storage pool to which charge is returned for use on subsequent calculations.

Referring to FIG. 2C, to implement an XOR function 18 one may need to add an additional element—a sense gate SG. A sense gate SG in CCD logic may be a floating diffusion or poly gate which is regularly reset to a potential and whose potential drops once charge is moved underneath it. It is beneficial to further add gain to the sense gate such as by coupling to it a high gain element such as a thyristor. Hereafter we will refer to a sense gate as if it included gain. By coupling the AND output to a sense gate (SG), and thereafter to a barrier one can sink the charge in the summing node and thereafter the summing node would represent XOR functionality.

The XNOR above can be extended to a half adder 20 as may be shown in FIG. 2D by capturing the extra charge (SG node) as a carry bit or accepting the SG output (for example of the thyristor) as the carry bit. If the B output is always provided a ‘1’ then the carry output may equal A and the sum may be the complement of A (inverter). If the B is fed from an ID, then the output may always be refreshed to a fill bin level which may be used from time to time to reduce charge loss in a logic function.

A full adder may be implemented by adding a third input to the summer, and an additional barrier and charge storage bin in series with the first barrier and charge storage bins where said second charge storage bin actuates the refill (for example if it is coupled to a sense gate) of the input summer if it is actuated, where the first represent the carry bit of the full adder.

The downside of (B) CCD based logic is the need for interim storage locations and barriers whose size is on the order of the input bins, as well as potential limitation if the logic element is complex (deep). It is also slow due to the time constant of charge movement between bins. To be compatible with modern digital flows it would be better if we could find a way to implement our gates without the above disadvantages.

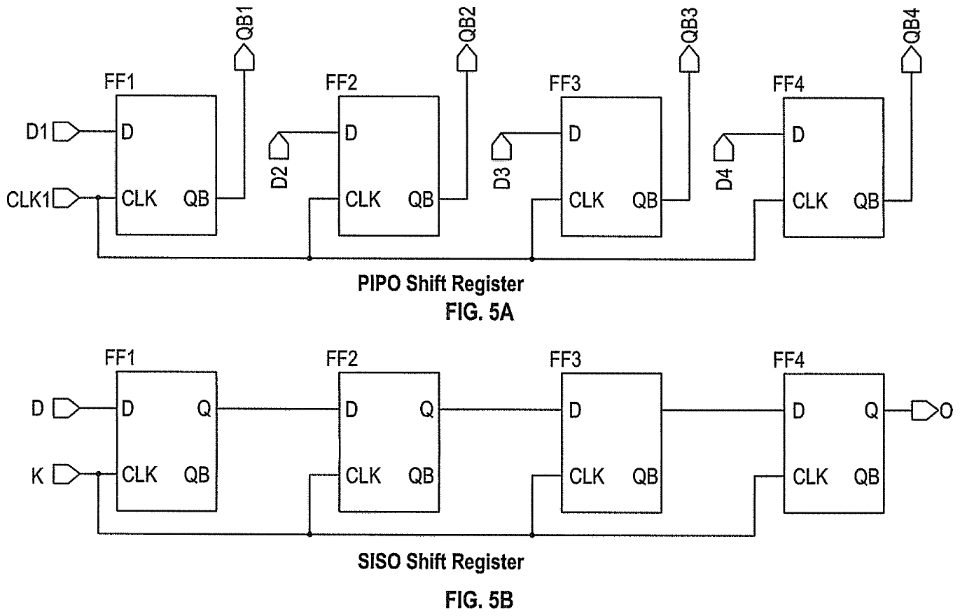

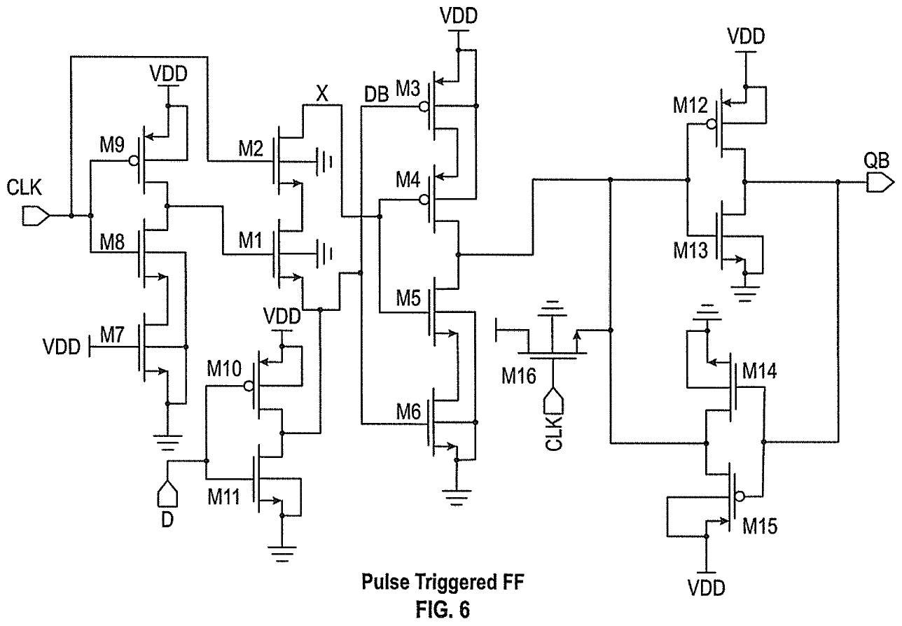

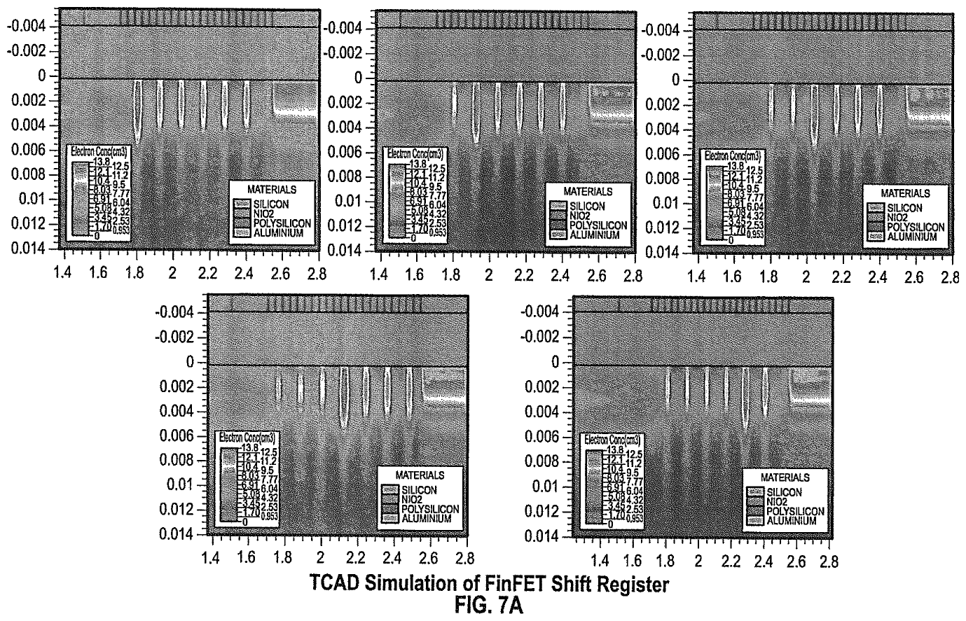

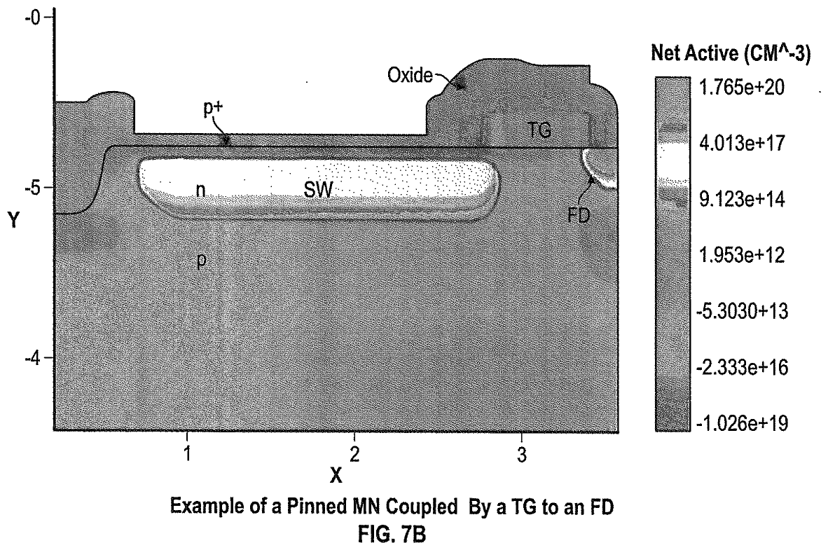

A charge domain shift register may illustrate the advantages of charge based digital processing vs. transistor based digital processing. In FIG. 5A-5B, one may see examples of parallel and serial shifts registers built from flip-flops, while in in FIG. 6, one may see an example implementation of each of those flip flops using a plurality of transistors. The number of transistors and the number of switching transistors with a direct path from vdd to gnd can be seen from the circuit shown in FIG. 6. If these shoot through currents and the flushing of charge and re-filling of charge with each move of the shift register (even if it is a wired feedforward or feedback shift register) represents a great deal of lost power. Instead in FIG. 7A, results of TCAD simulations of a Fin based shift register may be seen. In accordance with one embodiment, the Fin based shift register was simulated in TCAD at 1 GHz using a 7 nm gate length FIN process (where the simulation in TCAD had to be done as a surface device, however, the parameters were modified to simulate the performance of a FIN based device). It can be seen that the shifting of charge in the Fin based shift register does not involve the loss of charge each time the charge moves to the next element-charge is conserved. Additionally, the gate charge (current) requirement is lower than that required by the digital implementation due to reduced parasitics, no drain and source, and the saving of the charge required to satisfy the miller effect, which saves the power associated with gate clocking.

In the following one may teach better implementations of charge domain digital logic processing.

### ID & Transfer Gate Logic (ITGL)

It may be common in pixels to utilize pinned memory nodes and to enable transfer of charge between those memory nodes through the use of transfer gates (TGs). This works differently to CCD logic in that the potential of the storage well diffusion in a pinned memory node drops as it is filled with charge from the level it is pinned at. This is further illustrated in FIG. 7B where the pinned memory node is the p+, n structure on the left within the p substrate (looks like a shorted bipolar transistor or JFET). The TGs may lower the potential between the memory nodes so as to allow charge to transfer from one to the other. The absence of a drain or source may make them very compact compared to MOSFETs. A disadvantage is the need for the bins to be at a lower potential than the one from which the charge is moving to increase the speed of transfer. This may limit the effective potential range and number of elements in a logic function. Alternatively bins or memory nodes may be MOS capacitors operating between deep depletion and weak inversion.

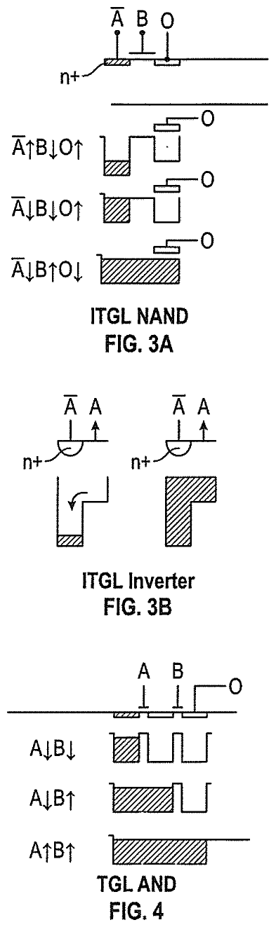

The simplicity of an ITGL gate may be shown in FIG. 3B. Here an ID may be fabricated next to a memory node. If the voltage on the ID diffusion (e.g. n+) is raised then the diode charge level will fall. More specifically, the depletion region will expand under the n+ diffusion if the potential on n+ is raised. This may cause charge in the adjacent bin to conduct back into the diode depletion region. If the ID voltage is lowered then the depletion region will shrink and carriers will transfer from the ID into the memory node which could be used as an input for subsequent ITGL logic functions. This example implements inverter functionality.

Extending this concept, one can use the complement of the input, a TG, and a memory node to implement different logic gates. For example if we label the ID input as A_, then A NAND B may be reflected on the output sense gate (or an AND if we utilize the charge output). This concept may be illustrated in FIG. 3A.

If we use two IDs with inputs A_ and B_ each with a fixed barrier lower than the full charge potential of the IDs to an output memory node then that output will represent an OR'ed output.

To implement XOR, HALF ADDER and FULL ADDER functionality, one can again make use of sense gates and transfer gates to clear the output. One may introduce one or more thyristor elements which may ‘fire’ when charge is introduced to its injection gate. These thyristors then may be used to raise or lower a barrier or activate a sink to clear the output. In the case of XOR and HALF adder a single barrier and SG is sufficient. For a full adder two barriers and two SG are required. The first SG in both cases is the carry. The second SG discharges the output node (summing node) in the FULL ADDER. This will be described in more detail when notch and barrier charge domain logic (NBCDL) is introduced below.

### Transfer Gate Logic (TGL)

Instead of controlling the ID, one may now assume all inputs are voltage inputs coupled to transfer gates, with free carriers supplied by the ID or the charge output from a previous logic circuit with the depletion level minimum potential above the MN or bin minimum. As shown in FIG. 4, one may simply lower two series transfer gates or barriers blocking free carriers from an ID to implement an AND gate. An OR gate may be created by separating two IDs with TGs to a common output memory node (MN).

XOR, HALF ADDER and FULL ADDER may be achieved by erecting barriers controlled by sense gates to isolate output memory nodes coupled to thyristors to actuate a sinks. This may be further described below.

Although ITGL and TGL may solve the problem of having to use multiple clock cycles to complete a logic function (they operate as soon as the inputs change), they still use charge bins which may require a relatively large quantity of charge. That charge has to be stored somewhere for reuse or flushed as it was in the (B) CCD case which is inefficient.

Now one may introduce a CDL methods which utilizes a minimum of charge, and is edge triggered without the need for multiple clock cycles for each logic gate.

### Notch and Barrier Charge Domain Logic (NBCDL)

The lowest power CDL implementation one may call notch and barrier charge domain logic (NBCDL). NBCDL may be a special type of TGL and edge logic based implementation in that charge may be actually transferred during edge transitions. NBCDL may be very efficient because one may work with small defined quantities of charge to implement logic rather than utilizing full wells, and one can make use of one's knowledge of the notch size to establish corresponding barriers so as to implement barrier based carry.

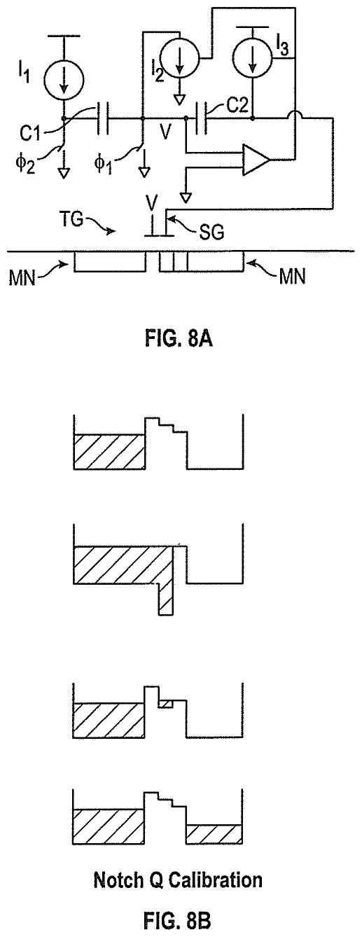

To understand a notch consider FIGS. 8A-8B. Here one may see a source of charge, such as an MN, bin (mos capacitor) or an ID separated from another MN. In this case one may separate two memory nodes (MNs). The notch gate consists of three elements fabricated in p substrate. A fixed barrier FB just to the left of the rightmost MN formed by a diode (p+ at the surface), a transfer gate TG formed to the right of the leftmost MN, and a notch created by an n+ implant whose minimum potential when the transfer gate TG is high is lower than the transfer gate minimum potential, between the fixed barrier FB and the transfer gate TG. The notch gate may be designed to keep charge from spilling back into the leftmost MN during transitions. If the transfer gate TG and notch are controlled by a single gate then the notch may be fixed in size and move with the transfer gate. If the notch potential is high (gate is low or negative) then the charge may be blocked in the leftmost MN or the rightmost MN. If the gate is high then the transfer gate bin bottom potential may be approximately that of the leftmost MN and the notch extends well below this MN, while the barrier is always at a fixed potential. If the gate is taken to low potential (we shall say low to mean low voltage or negative voltage) then the transfer gate TG maintains its potential higher than the notch potential during the transition and the charge in the notch during the transition will be trapped between the transfer gate TG and the fixed barrier FB. Eventually, the charge in the notch will spill into the rightmost MN over the fixed barrier FB which is lower in potential than the TG when the control gate is low. The benefit of this structure is that one can now work with very small quantities of charge instead of filling charge receptacles completely until the very end of the logic function, at which time a sense gate like a thyristor may be triggered by this output and the thyristor may couple a rail to a wired output or may cause charge to fill or empty a bin representing a charge output.

An additional innovation may be to control the depth of the notch. This may be done by splitting the common gate previously over the transfer gate TG and the notch. The problem, however, is that it may be very difficult to know exactly how much voltage difference on the split gate SG (not to be confused with sense gate) corresponds to the notch depth. One may calibrate this by utilizing the structure shown in FIG. 8A where two series capacitors C1, C2 may be used to accurately multiply a known input charge on the capacitor C1 and the input charge on the capacitor C2 (voltage across). The capacitor C2 may control the depth of the notch by creating a potential across the capacitor C2 relative to the control input previously connected to the gate over both the TG and the notch. In this case each of the terminals of the capacitor C2 are coupled to each of the split gates SG and one side of the split gate SG is controlled by the control input. As the right side of capacitor C2 may be at lower potential than the left side controlled by the control gate therefore the notch will be lower than the control gate minimum set on the TG. One may do a calibration to correlate against the barrier. Once may increase the input charge by small increments (once the barrier height overflows one may know we reached the height, which can be detected by a sense gate coupled to the right MN) during a calibration phase. In FIG. 8A, during phi1, one may load a known charge onto the first capacitor C1 corresponding to said barrier height, while during phi2 a comparator coupled to the node between capacitors C1 and C2 goes negative until the current sources controlled by the comparator return the node between capacitors C1 and C2 to ground. If the third current source charging both capacitors is modified by the second current source at the shared node by reducing the current charging the first capacitor by 2× for example, then we would have a notch corresponding to half the barrier charge height. By controlling the current ratio between the two rightmost current sources one may charge the first capacitor C1 more slowly than the second capacitor C2 and thereby control the charge ratio between the first and second capacitor C1 and C2 to adjust the notch height. The high impedance connections to the split gates SG may now be maintained such that they may be raised and lowered with the gate control that would have been used if they were a common gate, if said control is coupled to the node between the two capacitors C1 and C2, the current sources are off and phi1 and phi2 are off. In other configurations, barriers may be similarly established where the height is set in an analogous manner to the above. Further the gate connections may be reversed to establish a barrier rather than a notch. The potential between the two gates is maintained by the differential potential (on the capacitor) while a control gate may control the first gate and therefore the second gate plus or minus the capacitor potential.

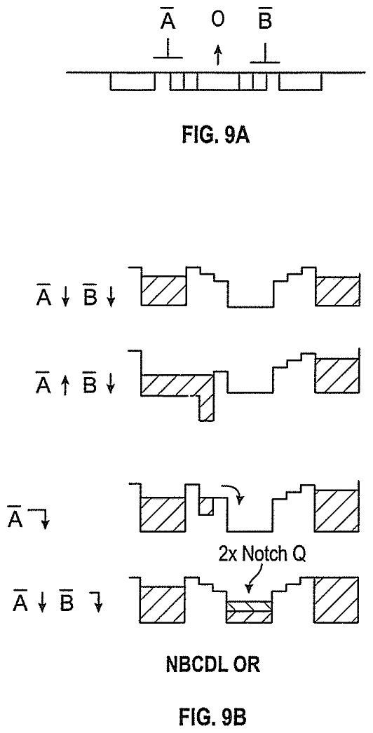

Referring to FIGS. 9A-9B, an OR gate based on NBCDL logic may be shown. The inputs may be complementary logic initially at high potential. On either side a source of charge may be shown. If either input transistor transitions it will collect a notch full of charge and transfer it to the output. If a barrier is created in a third direction (e.g., facing out of the page in the figure) with a barrier height corresponding to higher than a single notch's worth of charge but less than two notches worth of charge, then charge may spillover if both inputs were transitioned high and therefore we have AND functionality.

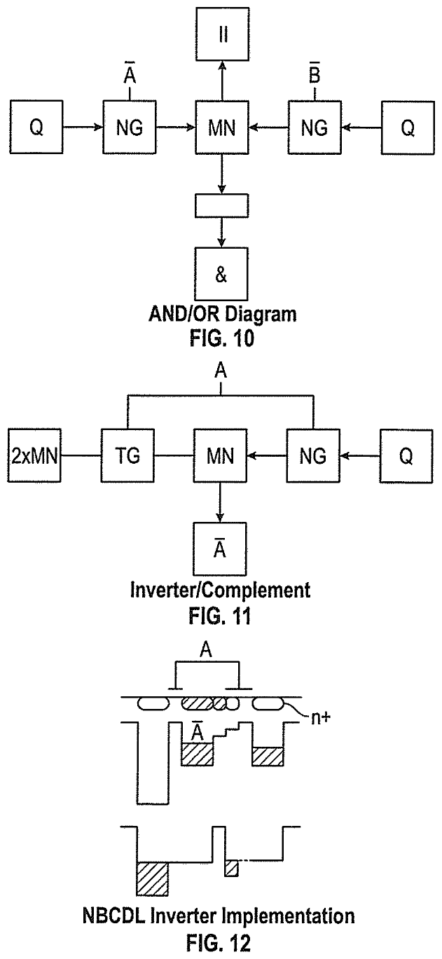

In FIG. 10, block diagrams of the OR/AND configurations of FIGS. 9A-9B may be seen. In FIGS. 11 and 12, a block diagram and an inverter based on NBCDL logic may be shown. In FIG. 12 the charge may be loaded for use with the next edge at the end of the previous operation. In this way one can work with a minimum of charge loaded into the subsequent notch input such that logic functions may be coupled, the input to successive logic functions actuating on edges, and one may not need to use a full bin of charge until producing an output. This means far less charge is transported through the logic function until the very end saving power and charge.

### Sense Gate

A floating diffusion reset each cycle or poly gate may be used to sense a change underneath it (capacitance change due to depletion region depth change). In pixels, this sense diffusion may be often coupled to a follower for readout. It may also be used, however, as a control signal for other transfer gates or to raise or lower barriers, to open or close notch gates, or to open or close paths between charge coupled storage elements, or to control paths to or depth of sinks. Unfortunately, the potential difference associated with the sense gate may not be sufficient to raise or lower a barrier elsewhere. To amplify this potential (or reverse polarity) the floating diffusion sense gate may be coupled to higher gain elements such as thyristors, MCT (mos controlled thyristors), bipolar transistors or other structures. In the case of the thyristor sense gate, its current trigger may be actuated by the movement of charge into its sense gate, or the output such as the n+ diffusion potential could be coupled by wire to a high impedance or charge trigger gate. The high gain of the thyristor may then be used to couple a control gate elsewhere to a power rail or control voltage (i.e., it turns on thyristor to create a path in conformance with the output of the logic function).

As mentioned, the thyristor may be integrated as an extended diffusion to the thyristor structure or the diffusion may be coupled by a wire to a thyristor device. It may be necessary to reset floating diffusions similar to resetting the floating diffusion in a 4T pixel by a MOSFET. This can also be accomplished through the thyristor. Care must be taken to ensure that the thyristor is not triggered during reset. There are many techniques to protect against false turn on, for example as used in thyristor based memory elements (capacitor coupled injection gates for example).

### Mixed Logic

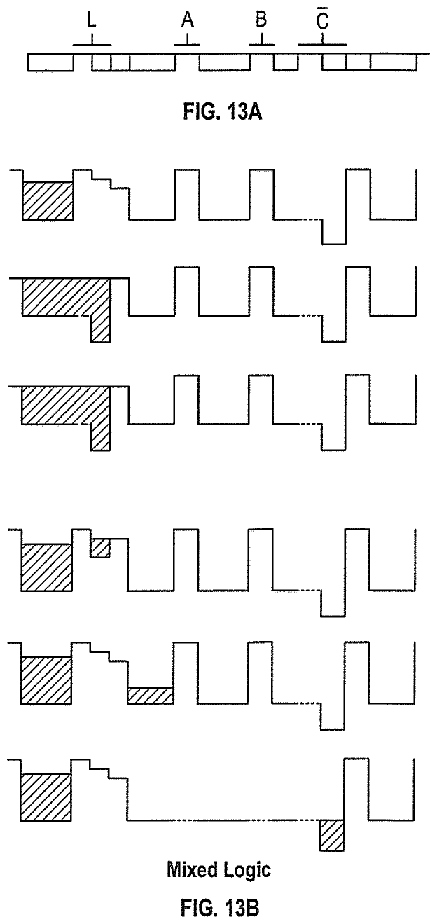

In FIG. 13A-13B an example of mixed logic may be disclosed. Here we can see that a minimum charge may be loaded from an input charge storage reservoir (for example an input diode or the previous logic function). This minimum charge may then be available for subsequent logic without wasting additional energy. In this case one may implement AB (A&B). The result may then be loaded into a subsequent notch such that an edge on C_ would load the result into the next stage such as might be useful in the first stage of a full adder for example. In the present embodiment, one may see mixed logic where an NBCDL notch is used to bring in the initial charge. Thereafter TGL logic may be used until an NBCDL notch is again used to produce the final output. The final MN may be coupled to a thyristor or be replaced with a sense diffusion (n+) to produce a full well or VDD or GND output.

This mixed logic illustrates some of the benefits of using a notch gate. Specifically, that one may not need to have a lower potential for each bin or MN to encourage the fast movement of charge from one to another. Instead this much smaller quantity of charge fills more quickly and since it is lifted and transferred to the next bin or MN, the bin or MN may be at substantially the same minimum potential bottom as the other while still retaining a large potential difference to drive the charge transfer. If it were not for this one may struggle to create a succession of logic gates without some sort of structure to start again at a higher potential level due to our limited potential dynamic range.

### Half Adder

| A | B | Σ | C |
|---|---|---|---|
| 0 | 0 | 0 | 0 |
| 0 | 1 | 1 | 0 |
| 1 | 0 | 1 | 0 |
| 1 | 1 | 0 | 1 |

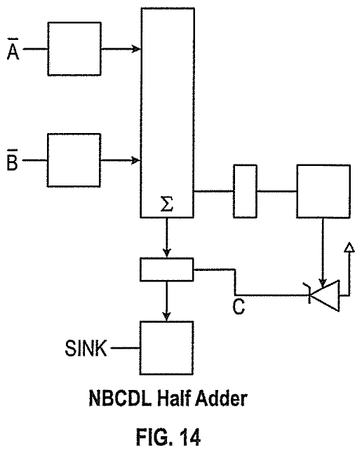

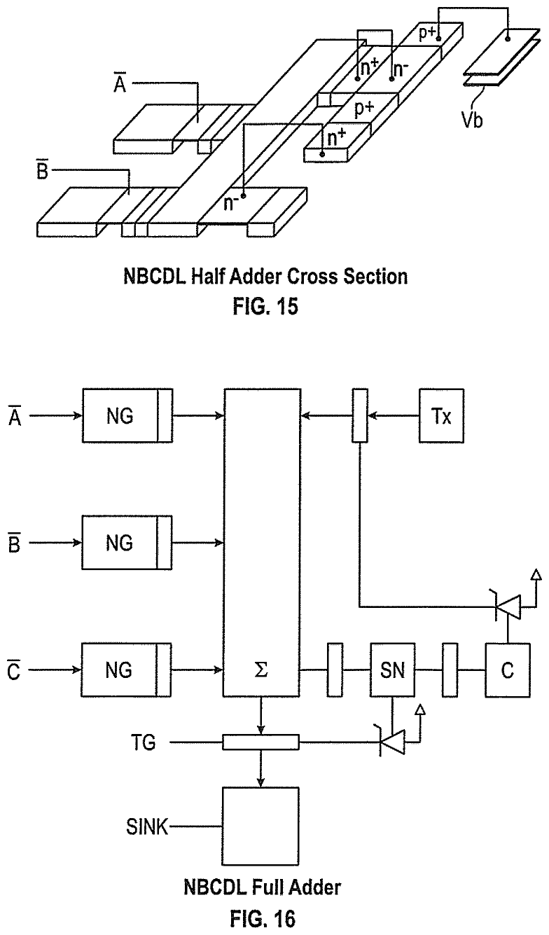

The truth table above illustrates the truth table of a half adder. FIG. 14 shows the block diagram of an NBCDL half adder while FIG. 15 shows the cross section of the half adder. The implementation is a subset of A full adder which is described in more detail in the following section. The idea here is to load notch gates with their input charges and at the edge allow the notch gate to move those charges into a shared MN. A fixed barrier of height corresponding to a single notch charge may allow charge to spill across the barrier if both inputs are high. This charge may be used by a sense gate, such as a thyristor based sense gate, to create a sink or to lower a barrier to a sink such that the shared node has its charge removed to implement the half adder sum functionality. The output of the sense gate itself may be used as the carry.

### Full Adder

| A | B | C | Σ | C |
|---|---|---|---|---|
| 0 | 0 | 0 | 0 | 0 |
| 0 | 0 | 1 | 1 | 0 |
| 0 | 1 | 0 | 1 | 0 |
| 1 | 0 | 0 | 1 | 0 |
| 0 | 1 | 1 | 0 | 1 |
| 1 | 1 | 0 | 0 | 1 |
| 1 | 0 | 1 | 0 | 1 |
| 1 | 1 | 1 | 1 | 1 |

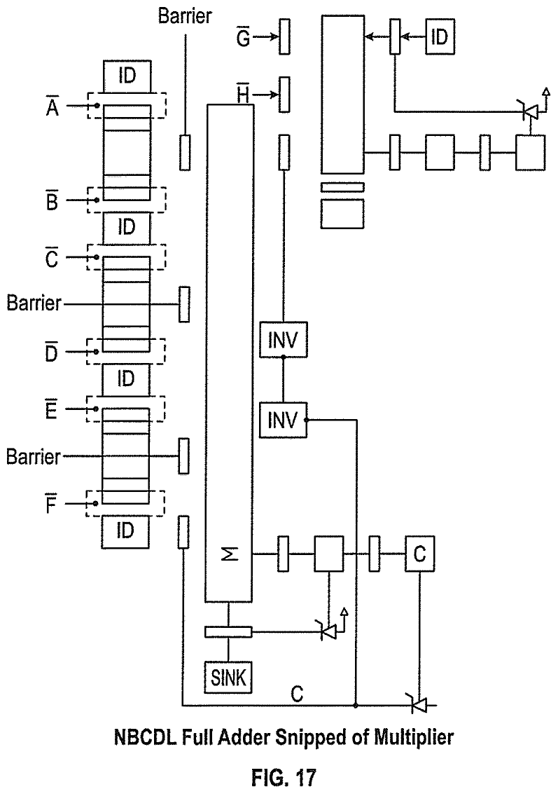

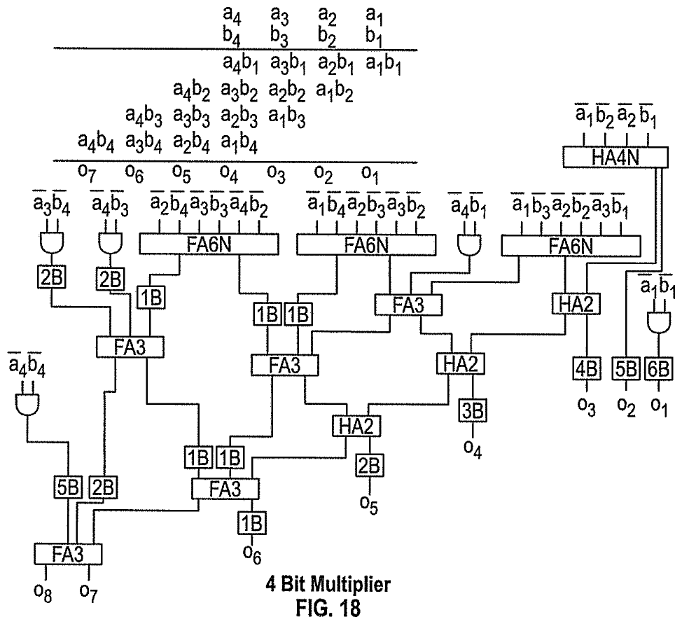

The truth table for a full adder may be seen above. FIG. 16 illustrates a full adder in block diagram form and FIG. 17 illustrates a portion of a 4×4 multiplier (the FA6N functionality of FIG. 18) including cross sectional implementation of three two input AND gates coupled to a full adder in addition to some other elements. The idea is to accept multiple notch gate AND inputs into a full adder. That storage element may be coupled to a barrier, memory node (of one notch size) and second barrier where each barrier is a single notch charge high. If only one of the inputs is high then no current will flow over any of the barriers and the output in the shared gate will be ‘1’. If two of the inputs are high then charge will flow over the first barrier into the memory node (sized to the equivalent of an input notch). A sense gate coupled to this memory node may then lower a TG to a sink or create a sink (sized to the equivalent of a notch) which will remove a notch worth of charge from the shared gate which may leave the output in the summing node ‘0’. If all three inputs are high (notch Q input×3) then both the first and second sense nodes would fill, the first sense gate may actuate the path to a sink MN, and the 3^{rd} charge packet may trigger a second sense gate. The second sense gate is coupled to a TG which may lower a barrier to a source of charge (e.g. ID) which may fill the shared gate (and sink) resulting in a ‘1’. The height of the ID may conform to the level of a single notch of charge in the shared gate for use with additional stages whose input is a single notch (although this is not strictly necessary). The output of the first sense gate is also the carry as with the half adder.

### Multiplication

FIG. 18 illustrates 4×4 operand digital multiplication, which simply does long hand multiplication shifting the result left for each of the second line operands and then adds the result. As NBCDL is edge logic triggered on a falling edge, therefore we need to work with the inverted input signals.

FIG. 17 illustrates the block diagram of a portion of the full adderThe inputs may be A_-F_ (inverted to be compatible with leading edge NBCDL logic). These inputs are coupled to notch AND gates (TGs which couple charge from ID's into a shared reservoir with a barrier one notch high so that only if both inputs are high charge will move to the shared gate. The shared gate may be the summing node of a full adder as illustrated in FIG. 17. The carry output of the full adder may be coupled to a pair of inverters (for a delay) before being coupled to another full adder. The additional half and full adders may be implemented in a similar way.

### FinFET

FinFETs have not been used for charge domain structures as they are not compatible with the lithographies used in image sensors. However, in the present case, we are using charge domain structures for digital charge domain processing and the present devices are not necessarily intended to be coupled to pixels. For this reason, one can take advantage of FINFET technology to implement our charge domain digital circuits.

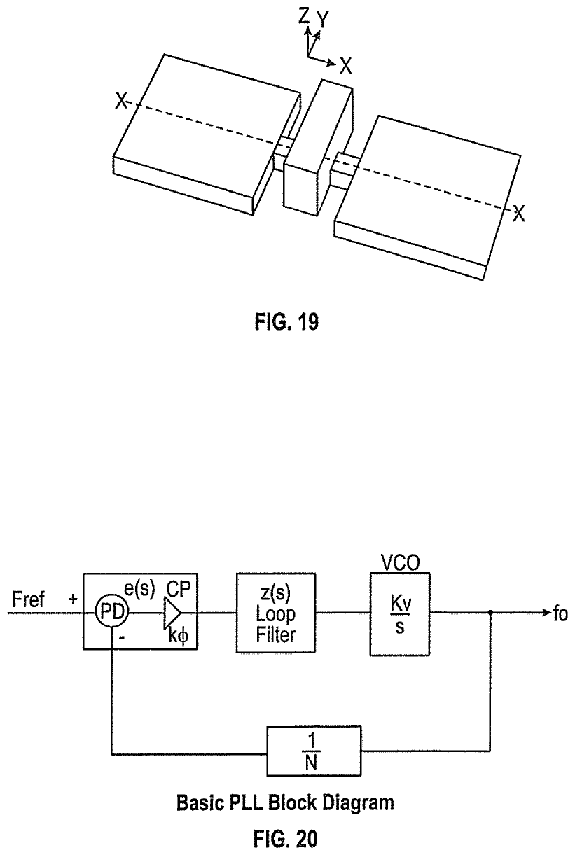

FIG. 19 illustrates the structure of a FINFET. The FINFET has several advantages: i) an isolated equivalent substrate around which gates may be partially wrapped which increases the equivalent gate area for each bin; ii) reduced parasitics due to the geometry; and iii) improved fringing fields to help move charge between MNs or bins.

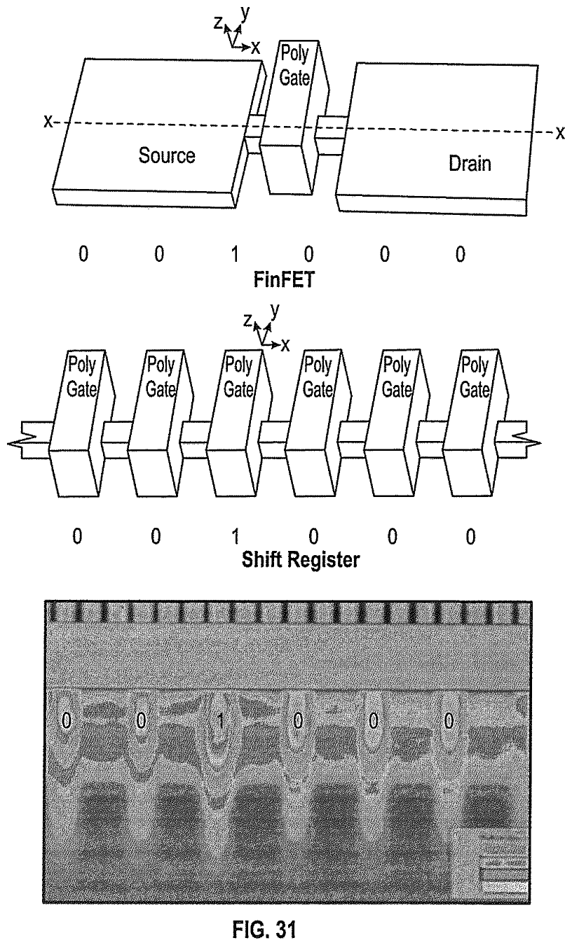

Examination of the structure shows how small the gate length may be compared to the size of the drain and source regions as shown in FIG. 19. Consider that charge domain devices, for example a charge domain shift register, eliminates these drain and source regions and only replicates the gate structure. This shows how the FIN can be used to improve the density of charge domain digital circuits compared to transistor based digital circuits as illustrated in FIG. 31. This is further enabled by the large SNR which allows a very small number of electron dynamic range. Digital transistors require far more electrons to switch efficiently. Additionally, the forces (especially fringe) which may be responsible for moving charge between shift register elements in the charge domain may be enhanced due to the wrap around gate structure, even where the FIN is doped to implement a buried (BCCD) structure. The FIN structure may be compatible with SCCD, BCCD, ITGL, TGL and NBCDL charge domain logic. In fact, calculations suggest that a 7 nm FIN operating over a 0.65V potential with a dynamic range of only 6000 electrons can switch at 1 GHz with reasonable charge transfer efficiency (CTE) for a (B) CCD type shift register or even less for a notch based shift register.

### Serdes

Serdes or serializer-deserializers are fundamental elements of today's communications and networking systems. The basic idea is to make parallel data serial and serial data parallel and recover and resequence the clock. Fundamental building blocks of a serdes include the PLL or phase lock loop which further includes a phase detector, charge pump, voltage-controlled oscillator, and frequency divider. There are many different topologies for PLLs including sigma delta implementations.

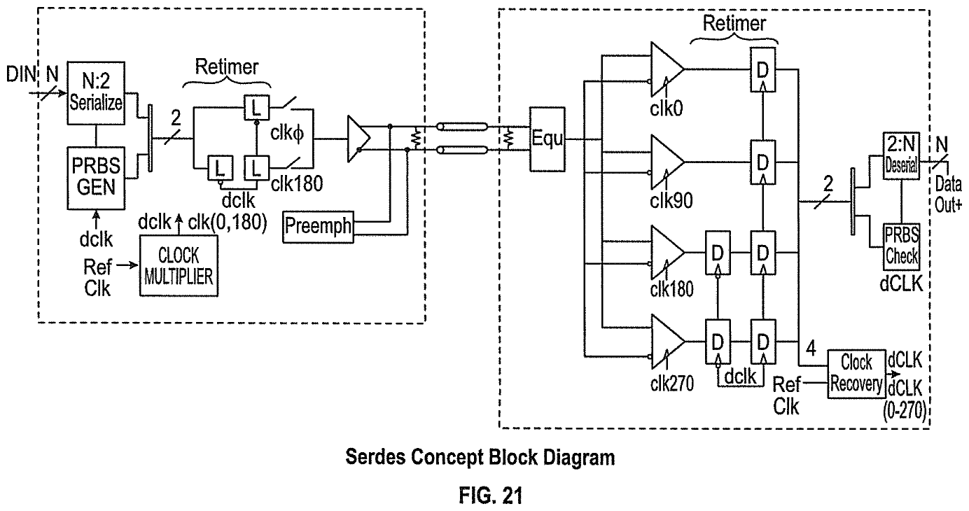

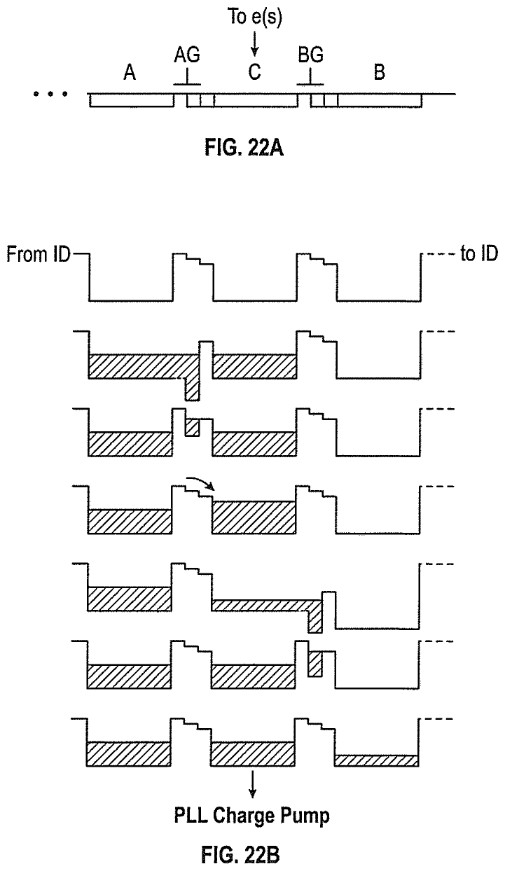

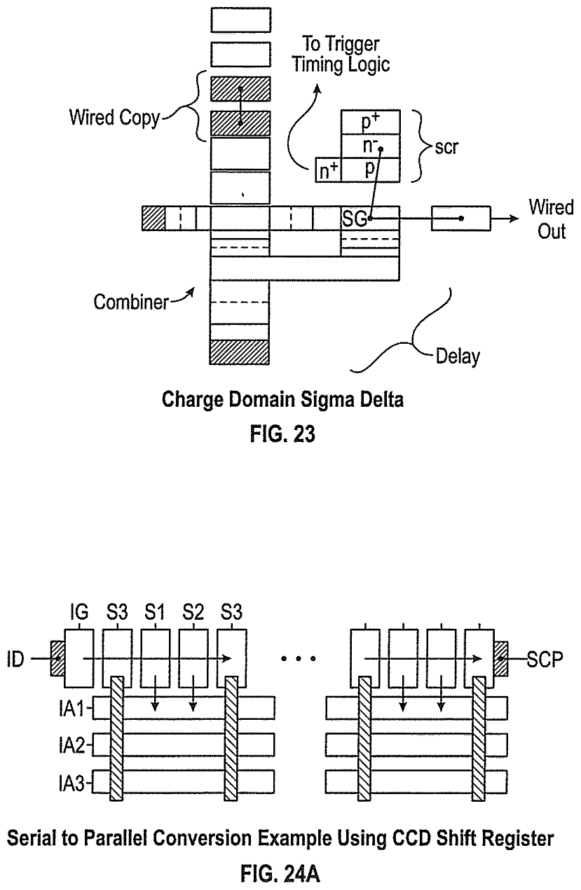

FIG. 21 illustrates the overall Serdes concept and FIG. 20 illustrates the block diagram of a basic PLL. FIGS. 22A & 22B illustrates the use of notch gates for a PLL charge pump where the center MN may be further coupled to a sense gate which controls the VCO frequency. Edge based NBCDL logic as described above may be used in the phase detector to clock the PLL charge pump using techniques similar to those used in transistor-based implementations. A fractional N sigma delta may be based upon a structure such as that shown in FIG. 23 which is a charge domain sigma delta (fed from the top).

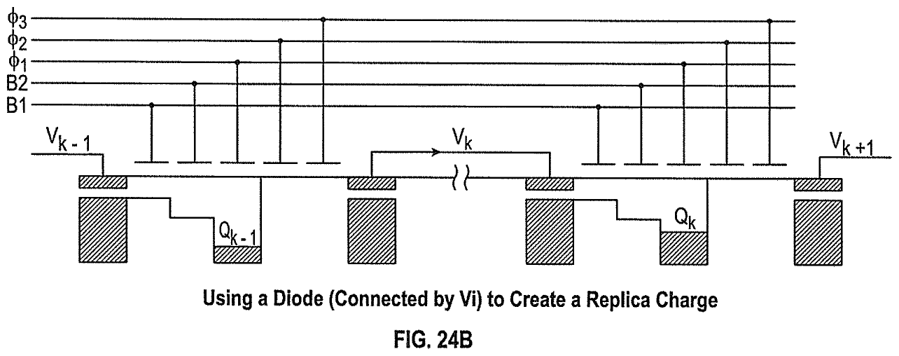

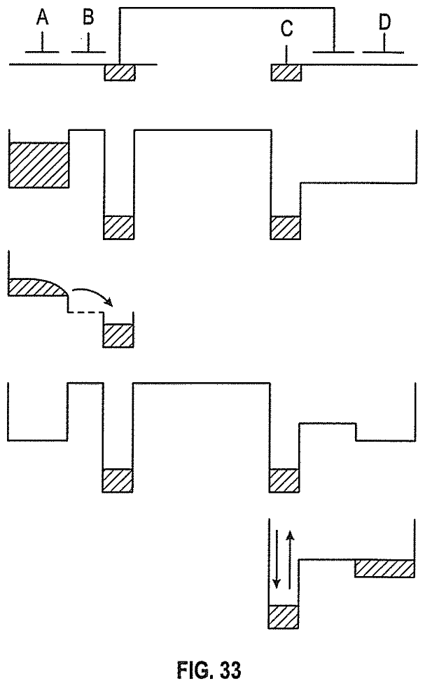

In certain cases it may be necessary to create a charge source input that is not destroyed by its use. This can be accomplished using a replicator as shown in FIG. 24B or FIG. 33.

The shift registers in CDL may be very efficient and therefore make a strong backbone for CDL Serdes implementations. A serial input can be easily loaded into a charge based horizontal shift register for example which can then be re-directed vertically for series to parallel operation, or in reverse parallel inputs can be easily moved vertically into a horizontal shift register and clock out serially. This is further illustrated in FIG. 24A. The half adder may also be used as a refresh element as described earlier.

### FPGA Functionality

The above illustrates that one can generate OR, AND, NAND, INVERTER, XOR, HALF ADDER and FULL ADDER using various charge domain methods. It has also been illustrated that one can erect or remove barriers between logic. One can also use shift registers to collect or direct the flow of outputs to additional logic in multiple directions simply by actuating control gates or using sense gates or wired connected IDs to create replica charge levels in different locations (see FIG. 24B as an example where Vi is common and the charge under the n+ regions will be replicated in both locations). The above flexibility allows one to implement custom logic functions in the manner of a field programmable gate array. In fact, the compactness and speed of these structures allows one to implement very efficient FPGA's that may be more efficient than standard FPGA's and due to the density of CDL, lower cost due to smaller die size, and lower power.

### GPT

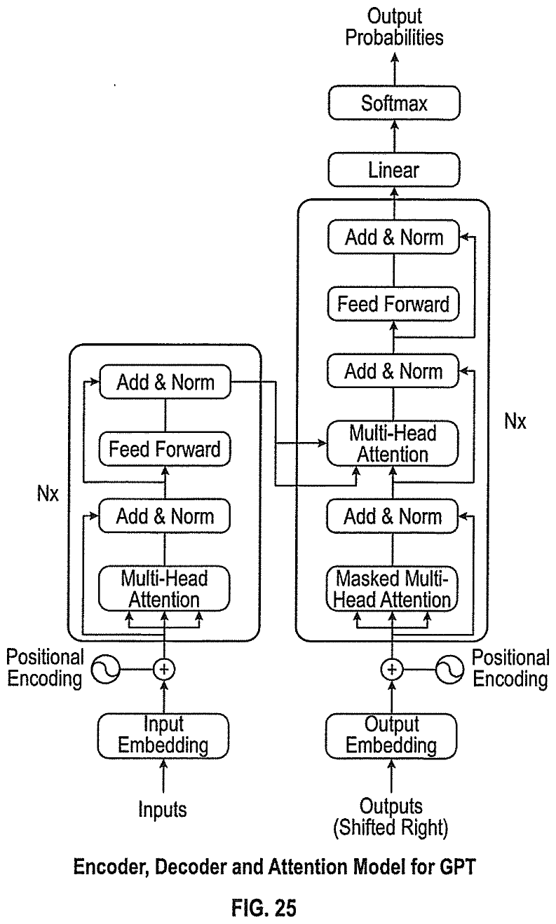

FIG. 25 illustrates the generative pre-trained transformer (GPT) model. The model my use multi-layer encoder and decoder blocks, position and attention blocks, to relate queries, tokens, and key-values to learned outputs. There may be a large amount of shift register based manipulation to implement these relationships which may be inefficient using the multi-transistor architectures of digital shift registers. By using charge based shift registers, one can increase the performance, reduce the power and shrink the size of the shift registers used to implement the GPT.

### SHA-256

A means of charge domain processing of cryptographic functions such as RSA (Rivest-Shamir-Adleman) or SHA (Secure Hash Algorithm), is taught. Cryptographic algorithms may be used in many applications to provide access or security, such as credit card or online transactions, bitcoin mining and processing of block chain parameters, and many other applications. Said cryptographic algorithms, in whatever application they are used, may require a significant number of mathematical operations ultimately requiring extensive use of shift registers, logic operations, ALUs (arithmetic logic units) or GPU (graphics processing units). A means of implementing these mathematical operations, and ultimately the algorithms of encryption using new and unique combinational logic, charge injection circuits, and optimized spill and fill structures to minimize the calculation of said parameters may be taught. As the charge domain processing conserves charge when compared to transistor based digital implementations, usually requiring fewer cycles to do so, the result is significantly lower energy use at an increased rate of calculation.

Cryptography and the calculation of complex formulas for the securing of information has long been an important part of information exchange, banking and financial transactions and storage. Cryptographic techniques may include schemes such as SHA-xxx and methods that use this technology such as block chain technology and the virtual currencies it has spawned have become a multi-billion dollar industry. Currencies such as bitcoin challenge “miners” to solve mathematical problems to be recognized as the owner of “mined” currency. Due to the large number and complexities of the calculations using transistor based digital solutions, for example to mine bitcoin, it is expensive both in terms of power and in terms of silicon, so expensive in fact that entire power plants are dedicated to the mining of virtual currencies.

Mining is a brute force approach involving the solving of cyptographic encryption schemes such as SHA-256. The mathematics of these schemes may utilize a significant number of rotate, shift, XOR, OR, and other logic functions which using transistor based digital techniques utilizes significant energy. These functions can be performed using traditional digital implementations, however, they can also be performed in an entirely different way using charge domain digital processing which may reduce the power consumption, and increase the rate of calculations, compared to traditional techniques.

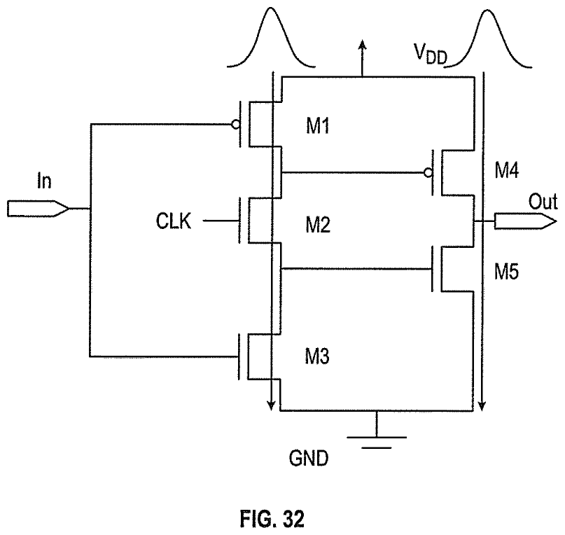

Referring to FIGS. 31 and 32, a five element flip flop and a FinFET containing only adjacent gates as in a charge domain shift register is shown. It can be seen that approximately six shift register elements including gate and MOS capacitor memory node may use a similar space to a single FinFET with a source and drain. As each of these elements represents the same functionality as the flip flop it can be seen that the size may be 30× smaller than a FinFET based shift register and simulations indicate that the power can be reduced by 22× or more.

FIG. 25 shows the encoder, decoder, and attention model for a generative pre-trained transformer. The layers of the encoder, decoder, attention vectors, and position vectors may be implemented efficiently by using one or two-dimensional charge based shift registers. By doing so benefits in power and density will accrue.

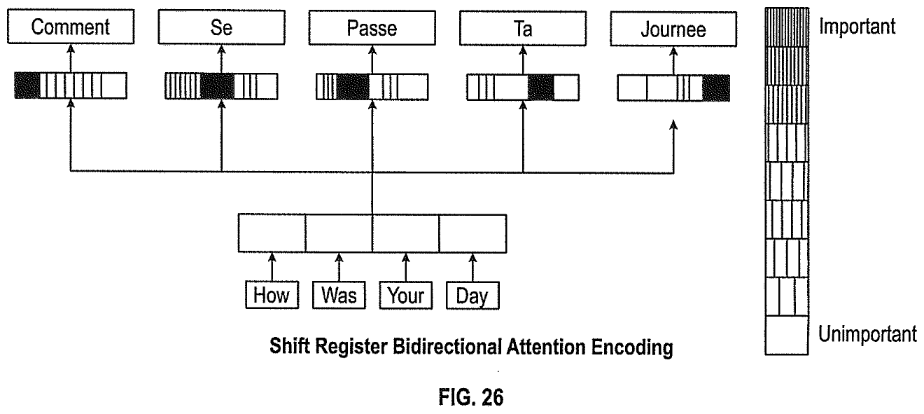

FIG. 26 illustrates encoder, decoder, attention and positional encoding concepts in a simple translation application. The key-values, tokens, weights, positions, etc. all need to be manipulated and stored over a large quantity of data during inference and during training. This can be done efficiently with charge-based shift registers and charge based digital functions.

The training of machine learning systems may be a cumbersome task involving the perturbation of weights and considering the change on outputs against an error function. The resulting contour over large number of perturbations can be used to determine an optimized set of weights that may result in minimizing the error function for a given weight set. This task requires the storage of a large number of variables and may be implemented using charge domain shift registers and digital functions.

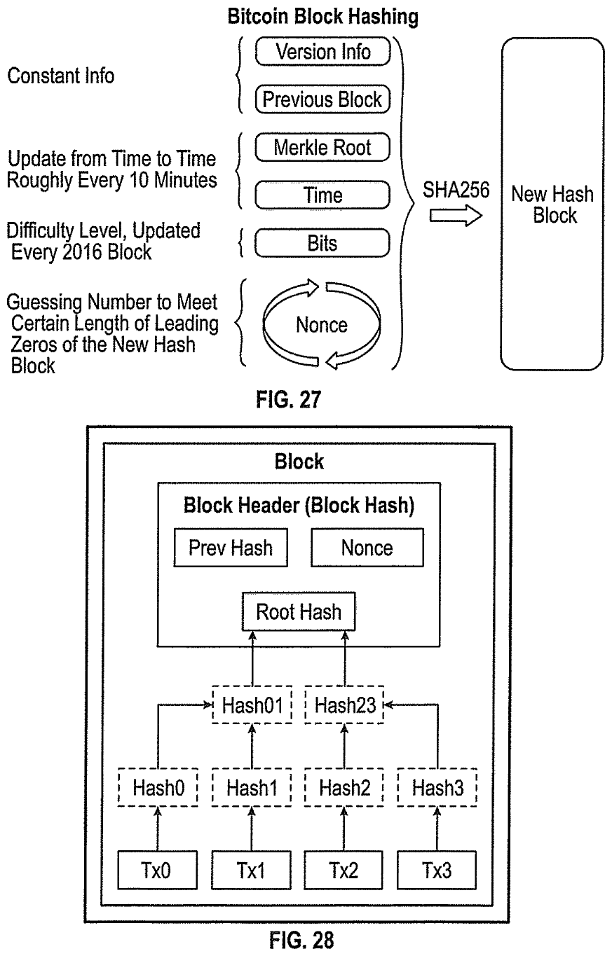

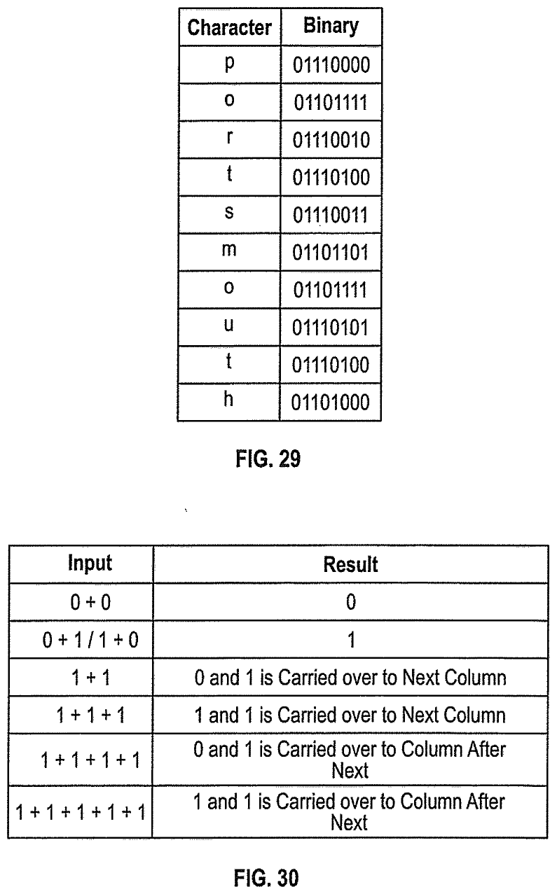

FIGS. 27 and 28 illustrate the Bitcoin virtual currency as an example of block chain techniques. It is the job of the miner to take a concatenation of historical and time data, and guess the remaining portion of a code. If the correct code is guessed then an error will be minimized and the miner may be credited with a certain amount of virtual currency as well as a small royalty on any future use of that virtual currency.

FIG. 31 shows the replacement of a FINFET with drain and source with a shift register charge coupled shift register equivalent to illustrate that a single FINFET could fit multiple charge buckets. In reality the gates would be closer together. The bottom figure illustrates the movement of charge through a charge coupled shift register to illustrate movement and digital representation.

FIG. 32 shows a five transistor flip flop that may be used as a storage element for a shift register. As each transistor is the size of a FINFET therefore more than 30 buckets could fit in the same area as a single element in a digital shift register if it were implemented with a FIN based shift register.

FIG. 33 illustrates a charge replicator. In this case the change a charge is moved under a sense gate and the potential difference used to raise a barrier next to an input diode (ID). Lowing and then raising the input diode potential will then fill an MN to the right of the barrier to the height of the barrier. As the height of the barrier is proportional to the charge residing under the sense gate, therefore we can use the charge on the rightmost MN and then fresh it as often as desired without losing the knowledge of the charge.

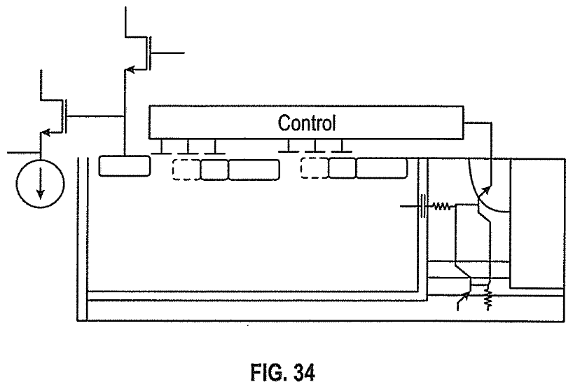

FIG. 34 shows shows MNs separated by notch gates, where the last MN is also coupled through a capacitor to a thyristor. The structure with the vertical dielectric sense gate on the final MN makes for an edge triggered sense gate that is very compact. The notch gates are connected to control circuitry such as that introduced earlier which can create different notch depths. As such the charge input to the first MN may be read in and out and controlled, and the charge transferred to the central MN and final MN may also be controlled. If the notch gate depth is controlled against a charge magnitude representing a weight and the first notch gates are cycled multiple times in proportion to an input then the circuit can be a multiply and add circuit (MAC). If a barrier is coupled to an output MN from the second MN then it may act as a decision function and the circuit implement neuron functionality. For example a ReLU is implemented if the barrier is at 50% such that an output only starts occurring for positive inputs and said output is thereafter linear. If the MNs between the input and output MN accumulates until an overflow level which may be detected when the thyristor stops actuating after a notch gate clocking then the device may be used as a counter or timer.

The foregoing description is illustrative of particular embodiments of the invention but is not meant to be a limitation upon the practice thereof. The following claims, including all equivalents thereof, are intended to define the scope of the invention.

What is claimed is:

1. A digital circuit comprising:
at least one source of a charge;
at least one output charge storage element;
at least one transfer gate to raise and lower potential barriers between charge storage elements to allow charge transfer or a charge sink to remove charges;
where said at least one transfer gate or sink implements a logic function.

2. The digital circuit of claim 1, wherein said at least one charge altering device is at least one of a plurality of transfer gates each transfer gate raising and lowering potential barriers between said charge storage elements to allow charge transfer or a plurality of charge sinks to remove charge.

3. The digital circuit of claim 1, wherein the at least one output charge storage element is one of a pinned charge storage element, a memory node, a MOS capacitor, or a diode.

4. The digital circuit of claim 1, wherein at least one source of a charge is one of an input diode, a pinned charge storage element, a memory node, or a MOS capacitor.

5. The digital circuit of claim 2, wherein the said at least one of transfer gates or sinks are responsive to edge transitions on their control gates.

6. The digital circuit of claim 1, comprising at least one of fixed barriers, gated barriers, sinks, or notches implemented using at least one of surface or bulk doping.

7. The digital circuit of claim 6, wherein the at least one of fixed barriers, gated barriers, sinks, or notches are fabricated under a common transfer gate wherein the at least one of fixed barriers, gated barriers, sinks, or notches move up and down in conformance with potential changes caused by the transfer gate.

8. The digital circuit of claim 5, wherein said at least one transfer gate is a notch gate type of transfer gate to limit the charge required to implement a given digital function.

9. The digital circuit of claim 8, comprising splitting said notch gate type of transfer gate and controlling a depth of a notch of said notch gate type of transfer gate, wherein a single input controls said notch gate type of transfer gate that has been splitted.

10. The digital circuit of claim 1, comprising a sense gate coupled to said at least one output charge storage element.

11. The digital circuit of claim 10, wherein said sense gate is one of a thyristor sense gate, a floating diffusion sense gate, a bipolar transistor sense gate, or a MOSFET sense gate.

12. The digital circuit of claim 1, implementing OR gate functionality comprising:
a plurality of transfer gates each responsive to a control input, wherein when any of said plurality of transfer gates are lowered in response to a respective control input, said at least one output storage element will accumulate charge.

13. The digital circuit of 1, implementing AND functionality comprising:
one or more memory charge storage elements coupled to said at least one source of a charge by at least one transfer gate, barrier or sink;
wherein charge flows to said at least one output charge storage element in response to lowering of said at least one transfer gate, barrier, or raising of sink;
wherein when said barrier or sink is used, said barrier or sink allow charge on the output only if total charge introduced to the logic gate is coincident with all inputs, whether charge inputs and or gate inputs, being logic high.

14. The digital circuit of claim 12, wherein the charge associated with all inputs being high at said output storage element of said AND functionality further actuates a sense gate which removes charge from said output storage element using a sink to implement XOR functionality.

15. A NAND ID and Transfer Logic Gate (ITGL) comprising:
an input diode coupled to a first control input;
a transfer gate coupled to a second control input;
an output memory node;
wherein an input diode potential is below a minimum potential of the output memory node when the first control input is high, wherein the transfer gate blocks conduction when the second control input is low, such that only when a potential minimum of the input diode is raised and a barrier is lowered can charge move to the output memory node.

16. An inverter ID and Transfer Logic Gate (ITGL) comprising:
an input diode coupled to a control input;
an output charge storage element adjacent to the control input and input diode;
wherein the input diode when the control input is low will bring charge above a potential of an output node causing charge to transfer to the output charge storage element and when high will sink charge previously in the output node emptying it.

17. A charge domain shift register, comprising:
a plurality of charge storage elements;
a plurality of transfer gates separating the plurality of charge storage elements; and
control inputs coupled to each of the plurality of transfer gates for controlling a depletion potential level under said transfer gates to erect or remove barriers;
wherein the plurality of charge storage elements and the plurality of transfer gates are fabricated on a fin.

18. A charge domain shift register, comprising:
a plurality of charge storage elements each responsive to a control gate;
control inputs coupled to each of the plurality of charge storage element control gates;
wherein the plurality of charge storage elements are fabricated on a fin.

19. The charge domain shift register of claim 17, wherein the charge domain shift register performs ROTR, ROTL, SHR, SHL functions for at least one of encryption or decryption algorithms.

20. The charge domain shift register of claim 18, wherein the charge domain shift register performs ROTR, ROTL, SHR, SHL functions for at least one of encryption or decryption algorithms.

21. A charge domain shift register, comprising:
a source of charge;
a plurality of charge storage elements;
an output charge storage element coupled to the plurality of charge storage elements;
a plurality of notch type transfer gates separating the plurality of charge storage elements; and
control inputs coupled to the plurality of notch type transfer gates;
wherein a charge is moved through the charge domain shift register by clocking the control inputs.

22. A logic circuit implementing XNOR functionality, comprising:
at least two sources of charge;
a summing memory node;
notch gates coupling the two sources of charge to the summing node;
a carry memory node coupled through a fixed barrier to the summing node, wherein a fixed barrier potential height is set relative to a summing node potential such that if all inputs to the summing node are high then charge transfers to the carry memory node over the fixed barrier, but if less than all inputs to the summing node are high then charge transfer to the summing node does not transfer to the carry memory node; and
a sense gate coupled to the carry memory node, wherein the sense gate further actuates a sink when charge is detected on the carry memory node, and wherein the sink is coupled to the summing memory node to remove the charge from the summing memory node in conformance with a signal from the sense gate.

23. The logic gate of claim 22, comprising a carry output comprising an output of the sense gate such that an XOR output in addition to a carry memory node output produces half adder functionality.

24. The logic gate of claim 23, further comprising a third input as well as a second barrier in series with said carry node followed by a second sense gate wherein the second sense gate actuates the refilling of the summing node and sink so that in combination with the summing node implements full adder functionality.

25. A 4×4 bit multiplier, comprising:
a combination of notch based AND gates coupled to a plurality of full and half adders built from notch gates, barriers and sinks, as well as additional notch based logic and output memory nodes.

26. A series to parallel converter, comprising:
an input source of charge;
a plurality of charge based shift registers, wherein a first charge based shift register coupled to the input source of charge, a remaining plurality of charge based shift registers orientated at an angle to each element of the first charge based shift register;
an output charge storage element coupled to each of the remaining plurality of shift registers;
wherein the first shift register accept series information from the input source of charge and provide the series information as parallel.

27. A parallel to series converter comprising:
a plurality input charge sources;
a charge based shift register at an angle to said plurality of input charge sources whose series elements are coupled to said plurality of input charge sources, wherein charge is loaded to the series elements of the charge based shift register according to a number of input sources and then shifted by the number of input sources; and
an output charge storage element coupled to the shift register;
wherein the output charge element provides the serialized output of the parallel inputs.

28. A serdes, comprising:
a series to parallel converter, comprising:
an input source of charge;
a plurality of charge based shift registers, wherein a first charge based shift register coupled to the input source of charge, a remaining plurality of charge based shift registers orientated at an angle to each element of the first charge based shift register;
an output charge storage element coupled to each of the remaining plurality of shift registers;
wherein the first shift register accepts series information from the input source of charge and provide the series information as parallel;
a pair of notch transfer gates separating sources of charge from a memory node;
wherein the notch transfer gates can one of move or remove charge from the memory node;
wherein the memory node is coupled to a sense gate which is coupled to a control node of a VCO used in the serdes.

29. A generative pre-trained transformer, comprising:
at least one charge based shift register;
wherein encoder and decoder layers of the transformer are built from the at least one charge based shift register.

30. The generative pre-trained transformer of claim 29, wherein attention layers are built from the at least one charge based shift register.

31. The generative pre-trained transformer of claim 30, wherein the transformer is a generative pre-trained transformer having at least one charge based shift register containing positional embedding information.

32. A machine learning training device, comprising:
at least one charge based shift register responsive to an error function;
wherein input information, tokens, values, keys, weights and other variables are stored in the at least one charge based shift register;
wherein a training algorithm follows a contour in conformance with an error function by perturbing said input information, tokens, values, keys and/or weights of a model.

33. A field programmable gate array, comprising:
charge domain logic (CDL) functions coupled to a plurality of charge based shift registers where sense gates may be selected to choose the output of each gate desired;
an input map corresponding to desired logic functions; and
a multiplexer coupling the input map to sense gates to the shift registers and said shift registers to each other so as to produce a succession of logic functions.

34. A dynamic digital memory structure comprising a plurality of charge based shift registers, wherein the plurality of charge based shift registers are one of one dimensional or two dimensional charge based shift registers.

35. The dynamic digital memory of claim 34 wherein the plurality of charge based shift registers are refreshed periodically.

36. A circuit to set a depth of a notch gate, comprising:
a charge storage memory node;
a charge domain notch gate coupled to the charge storage memory node;
two capacitors connecting in series;
a first current source coupled between a supply and a non-shared terminal of a first capacitor of the two capacitors;
a second current source coupled to a shared terminal of the two capacitors and ground or supply;
a third current source coupled to the non-shared terminal of the second capacitor;
a first switch connected between the non-shared terminal of the first capacitor and ground;
a second switch connected between the shared terminal of the two capacitors and ground;
a comparator connected to the shared terminal of the two capacitors on one terminal and ground on the other, the comparator coupled to actuate the second and third current sources when the shared terminal potential of the two capacitors is below ground; and
a notch gate controlling the notch depth coupled to a non-shared terminal of the second capacitor and the transfer gate portion of the notch gate coupled to the shared terminal.

37. The circuit to set a depth of a notch gate of claim 36, wherein the shared terminal of the two capacitors is coupled to the notch gate over a portion of the notch gate with no surface implant and the notch portion of the separated notch gate is coupled to the non-shared terminal of the second capacitor;
wherein the notch gate will actuate when the first and second switches and all current sources used to set the notch depth are off and in conformance with a control input coupled to the shared terminal;
wherein the depth of then notch was first set by loading a charge using the first current source with the second switch from the shared terminal to ground on during one cycle, and then turning off the first current source and second switch before turning on the first switch to ground from the non-shared terminal of the first capacitor during a second cycle so as to produce a known voltage across the second capacitor where the voltage magnitude is controlled as a ratio of the magnitudes of the second and third current sources and said notch is coupled to the non-shared terminal of the second capacitor such that the notch height is altered until the notch transfers a desired charge to the output memory node which may be measured by a sense gate coupled to the memory node or coupled to a floating diffusion through a fixed barrier coupled to the output memory node such that charge would not be detected until enough charge is transferred to overcome the fixed barrier such that the sense gate determines when the voltage across the second capacitor has created a notch gate depth of charge after which it may transfer proportional charge to control said notch depth against known barrier height charge.

38. A VCO control register, comprising:
a source of input charge;
a first charge based memory node coupled to the source of input charge by a notch gate;
a second charge based memory node whose charge level is set below the minimum potential of said first charge based memory node or a sink or a diode set below said minimum potential coupled to the first charge based memory node by a notch gate; and
a sense gate coupled to the first charge based memory node and an oscillator voltage based frequency control register;
wherein the oscillator frequency is regulated by control inputs which actuate the transferring of charge into and out of the first memory node to increase and decrease the voltage of the voltage based frequency control register.

39. A multiply and add circuit, comprising:
a source of charge;
an output memory node;
a memory node coupled by notch gates between said source of charge and said output memory node;
a control means coupled to said notch gates for controlling notch depth; and
a capacitor formed by a vertical dielectric separating the third MN from a thyristor;
said thyristor striking when the rate of change of the final MN exceeds a threshold whose output is further coupled to said control means;
where data input is a number of cycles the gate is actuated by said control means and;
where weights are the depth of the notch.

40. A neuron comprising
the circuit of 39 where said output memory node is further coupled to a barrier set in conformance with a desired decision function.

41. A timer comprising:
a source of charge;
an output memory node;
one or more memory nodes coupled by notch gates between said source of charge and said output memory node;
a control means coupled to said notch gates for controlling notch depth;
a capacitor formed by a vertical dielectric separating the output memory node from a thyristor;
said thyristor striking when the rate of change of the output memory node exceeds a threshold whose output is further coupled to said control means;
where the depth of each notch sets the number of actuations required to fill each memory node in turn and;
all memory nodes being full is indicated when the thyristor no longer actuates because charge cannot be transferred into the output memory node to produce a potential change to couple through the capacitor to the thyristor.

42. A replicator, comprising:
an input charge memory node; and
a sense gate coupled to said input charge memory node;
an input diode coupled to one side of a transfer gate capable of actuating a barrier;
wherein said sense gate further coupled to the control gate of said transfer gate barrier;
an output charge memory node further coupled to said transfer gate barrier;
wherein movement of charge to said sense gate from said input memory node raises the potential of said transfer gate erecting a barrier proportional in height to the input charge and;
wherein said input diode actuated so as to fill the output memory node with a charge coincident with the height of said barrier, by raising the charge level above and then the input diode charge level lowered by said barrier height, where said charge on said output memory node can be used and replenished by repeating the actuation of said input diode such that the output charge remains can be restored each cycle in proportion to the charge initially on the input charge memory node.
